(19) United States
(12) Patent Application Publication
(10) Pub. No.: US 2026/0026167 A1
(43) Pub. Date: Jan. 22, 2026

(54) DISPLAY DEVICE AND MOTHER SUBSTRATE FOR DISPLAY DEVICE

(71) Applicant: LG Display Co., Ltd., Seoul (KR)

(72) Inventor: Haesung LEE, Yongin-si (KR)

(73) Assignee: LG Display Co., Ltd., Seoul (KR)

(21) Appl. No.: 19/224,156

(22) Filed: May 30, 2025

(30) Foreign Application Priority Data
Jul. 18, 2024 (KR) 10-2024-0094763

(51) Int. Cl. H10H 29/49

(52) U.S. Cl. CPC H10H 29/49

(57) ABSTRACT

A display device and a mother substrate for the display device are discussed. The display device can include a substrate, one or more pixel driving circuits disposed on a substrate, micro LEDs electrically connected to the pixel driving circuits, and first electrodes electrically connected to the micro LEDs and the pixel driving circuits. Each of the first electrodes includes first to fourth conductive layers. Further, at least a part of a top surface of the second conductive layer is exposed from the third and fourth conductive layers. Accordingly, the second conductive layer which includes a material having excellent reflection efficiency is exposed to be used as a reflective plate which reflects light emitted from the micro LED to the top of the substrate.

### CROSS-REFERENCE TO RELATED APPLICATIONS

This application claims priority to Korean Patent Application No. 10-2024-0094763 filed on Jul. 18, 2024, in the Korean Intellectual Property Office, the entire disclosure of which is hereby expressly incorporated by reference into the present application.

### BACKGROUND

### Field

The present disclosure relates to a display device and a mother substrate for a display device.

### Discussion of the Related Art

Display devices are being applied to various electronic devices, such as TVs, mobile phones, notebooks, and tablets.

Among the display devices, there are an organic light emitting display (OLED) which is a self-emitting device and a liquid crystal display (LCD) which requires a separate light source.

In recent years, a display device including a micro light emitting diode (mLED or μLED) as a light emitting element is attracting attention as a next generation display device. The micro LED is formed of an inorganic material, rather than an organic material so that lighting speed is faster, a luminous efficiency is excellent, and an image with a higher luminance is displayed, as compared with the liquid crystal display or the organic light emitting display.

### SUMMARY OF THE DISCLOSURE

An object to be achieved by the present disclosure is to provide a display device with a simplified structure of a plurality of pixel circuits.

Another object to be achieved by the present disclosure is to provide a display device and a mother substrate for a display device in which a first electrode is used as a reflective plate which reflects light emitted from a micro LED.

Another object to be achieved by the present disclosure is to provide a display device and a mother substrate for a display device in which when a first electrode is formed, a module alignment key and a cell ID (identification) are formed together.

Still another object to be achieved by the present disclosure is to provide a display device and a mother substrate for a display device in which a conductive layer having an excellent reflection efficiency, among a plurality of alignment conductive layers of a module alignment key, is exposed to improve a recognition rate of the module alignment key.

Still another object to be achieved by the present disclosure is to provide a display device and a mother substrate for a display device in which a conductive layer having an excellent reflection efficiency, among a plurality of ID conductive layers of a cell ID, is exposed to improve a recognition rate of the module alignment key.

Still another object to be achieved by the present disclosure is to provide a display device and a mother substrate for a display device in which an adhesive characteristic between a cell ID and a module alignment key and a passivation layer is improved to minimize lifting of the passivation layer.

Objects of the present disclosure are not limited to the above-mentioned objects, and other objects, which are not mentioned above, can be clearly understood by those skilled in the art from the following descriptions.

According to an aspect of the present disclosure, a display device includes a substrate, one or more pixel driving circuits disposed on the substrate, a plurality of micro LEDs which are disposed on the pixel driving circuits and are electrically connected to the pixel driving circuits, and a plurality of first electrodes which are electrically connected to the plurality of micro LEDs and the pixel driving circuits. Each of the plurality of first electrodes includes a first conductive layer, a second conductive layer disposed on the first conductive layer, a third conductive layer on the second conductive layer, and a fourth conductive layer on the third conductive layer. At least a part of a top surface of the second conductive layer is exposed from the third conductive layer and the fourth conductive layer. Accordingly, the second conductive layer which is formed of a material having excellent reflection efficiency, among the plurality of conductive layers of the first electrode is exposed to be used as a reflective plate which reflects light emitted from the micro LED to the top of the substrate.

According to an aspect of the present disclosure, a mother substrate for a display device includes one or more scribing lines which define a display panel, a plurality of micro LEDs disposed in an inside area of the scribing lines, one or more pixel driving circuits disposed in the inside area of the scribing lines, a plurality of first electrodes which are disposed in the inside area of the scribing lines, and electrically connect the plurality of micro LEDs and the pixel driving circuits, and each of which includes a plurality of conductive layers, a plurality of module alignment keys which are disposed in the inside area of the scribing lines, and each of which includes a plurality of alignment conductive layers, and a plurality of cell IDs which are disposed in an outside area of the scribing lines, and each of which includes a plurality of ID conductive layers and the plurality of conductive layers. The plurality of alignment conductive layers, and the plurality of ID conductive layers are formed with a multi-layered structure with the same material. Accordingly, the plurality of module alignment keys, the plurality of cell IDs, and the plurality of first electrodes are formed by the same process to simplify the process and structure.

Other detailed matters of the example embodiments are included in the detailed description and the drawings.

According to the present disclosure, the plurality of pixel circuits is integrated in one pixel driving circuit to be efficiently driven at a lower power.

According to the present disclosure, a first electrode disposed below the micro LED is used as a reflective plate to improve luminance of the display device.

According to the present disclosure, an alignment conductive layer having a high reflection efficiency, among a plurality of alignment conductive layers which form a module alignment key, is exposed to improve a recognition rate of a module alignment key.

According to the present disclosure, an ID conductive layer having a high reflection efficiency, among a plurality of ID conductive layers which form a cell ID, is exposed to improve a recognition rate of a cell ID.

According to the present disclosure, a transparent conductive oxide layer disposed on an uppermost end of the module alignment key and the cell ID is minimized. Therefore, an adhesion between the module alignment key and the cell ID is improved and lifting defect of the passivation layer can be suppressed, prevented or minimized.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view illustrating a display device according to an example embodiment of the present disclosure;

FIG. 2 is a plan view of a display device according to an example embodiment of the present disclosure;

FIG. 3 is an enlarged view of a display device according to an example embodiment of the present disclosure;

FIG. 4 is a view illustrating a circuit structure according to an example embodiment of the present disclosure;

FIGS. 5 to 7 are plan views of a display device according to an example embodiment of the present disclosure;

FIG. 8 is a cross-sectional view of a display device according to an example embodiment of the present disclosure;

FIG. 9 is a cross-sectional view of a display device according to an example embodiment of the present disclosure;

FIG. 10 is a plan view of a mother substrate according to an example embodiment of the present disclosure;

FIGS. 11 and 12 are cross-sectional views of a mother substrate according to an example embodiment of the present disclosure;

FIGS. 13A to 13C are views for explaining a manufacturing process of a display device according to an example embodiment of the present disclosure; and

FIGS. 14 to 17 are views illustrating devices to which a display device according to example embodiments of the present disclosure is applied.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When explaining temporal relationships, terms such as “after”, “following”, “subsequent to”, or “before”, etc., can include non-consecutive cases unless terms like “immediately” or “directly” are used.

Terms such as “first”, “second”, etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) can be used. These terms are only intended to distinguish that one component from other components, and the nature, order, sequence, or number of the respective component is not limited by these terms.

When a component is described as being “connected”, “coupled”, “joined”, or “attached” to another component, it should be understood that the component can be directly connected, coupled, joined, or attached to the other component, but unless explicitly specified otherwise, it can also be indirectly connected, coupled, joined, or attached with another component intervening between each component.

When a component or layer is described as being “in contact with” or “overlapping” another component or layer, the component or layer can directly contact or overlap the other component or layer, but unless explicitly specified otherwise, it should be understood that it can also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but can indicate broader directionality within the range where the configuration of the present disclosure can function.

The features of various embodiments in the present disclosure can be partially or wholly combined or associated with each other, various technical interlocking and operations are possible, and each embodiment can be implemented independently of each other or can be implemented together in an associated relationship.

Hereinafter, an example embodiment of the present disclosure will be described in detail with reference to the drawings.

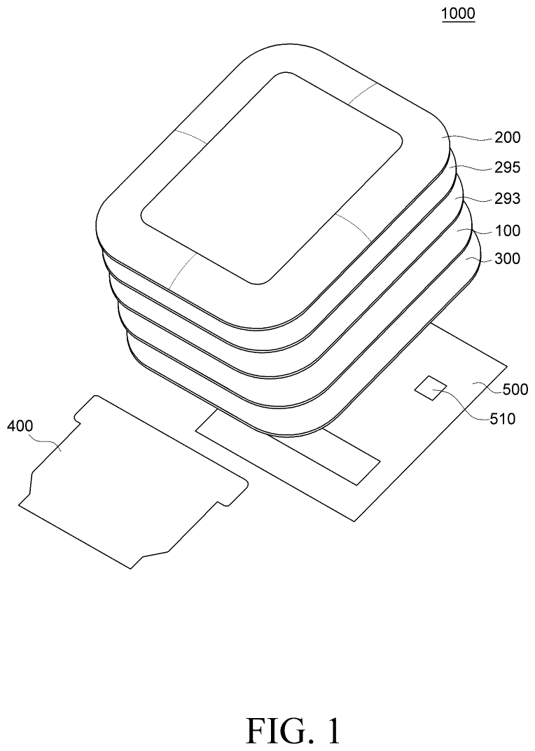

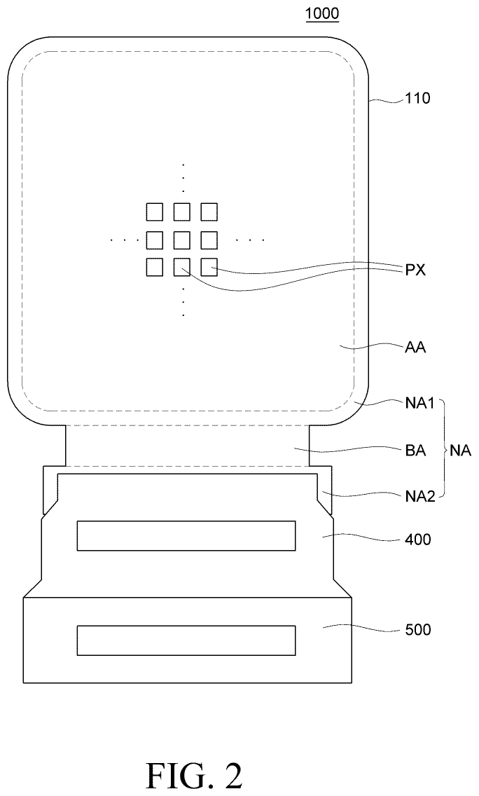

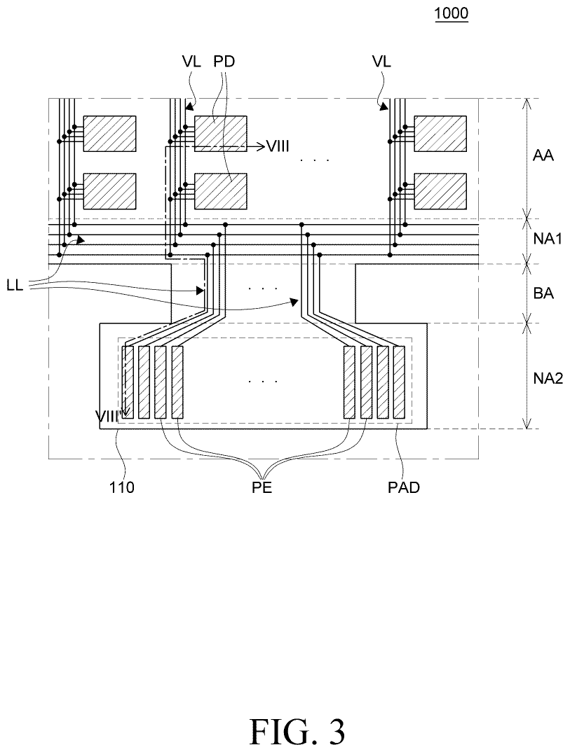

FIG. 1 is a perspective view illustrating a display device according to an example embodiment of the present disclosure. FIG. 2 is a plan view of a display device according to an example embodiment of the present disclosure. FIG. 3 is an enlarged view of a display device according to an example embodiment of the present disclosure.

Referring to FIGS. 1 to 3, a display device 1000 according to an example embodiment of the present disclosure can include a display panel 100, a polarization layer 293, an adhesive layer 295, a cover member 200, a support substrate 300, a flexible circuit board 400, and a printed circuit board 500.

For example, the display panel 100 of the display device 1000 can include a substrate 110. The substrate 110 can be a member which supports other components of the display device 1000. The substrate 110 is formed of an insulating material. For example, the substrate 110 can be formed of glass or resin. Further, the substrate 110 can also be formed of a material having a flexibility. For example, the substrate 110 can be formed of a plastic material having flexibility, such as polyimide (PI). However, the example embodiments of the present disclosure are not limited thereto.

The display panel 100 can implement information, videos, and/or images which are provided to users. For example, the display panel 100 can include an active area AA (or display area) and a non-active area NA (or non-display area). For example, the substrate 110 can include an active area AA and a non-active area NA. However, the active area AA and the non-active area NA are not mentioned to be limited to the substrate 110, but mentioned for the entire display device 1000.

The active area AA is an area where images are displayed. The active area AA includes a plurality of pixels PX. Each of the plurality of pixels PX can be configured by a plurality of sub pixels. A plurality of light emitting diodes can be disposed in each of the plurality of sub pixels. The plurality of light emitting diodes can be configured in different manners depending on the type of the display device 1000. For example, when the display device 1000 is an inorganic light emitting display device, the light emitting diode can be a light emitting diode (LED), a micro light emitting diode (micro LED), or a mini light emitting diode (mini LED), but the example embodiments of the present disclosure are not limited thereto. Hereinafter, the description will be made by assuming that the light emitting diode of the display device 1000 according to the example embodiment of the present disclosure is a micro LED, but the example embodiments of the present disclosure are not limited thereto.

The non-active area NA is an area where no image is displayed. In the non-active area NA, various wiring lines and circuits for driving the plurality of pixels PX of the active area AA can be disposed. For example, in the non-active area NA, various wiring lines and driving circuits can be mounted and a pad unit PAD to which an integrated circuit and a printed circuit are connected can be disposed, but the example embodiments of the present disclosure are not limited thereto.

For example, the driving circuit can be a data driving circuit and/or a gate driving circuit, but the example embodiments of the present disclosure are not limited thereto. Wiring lines through which a control signal for controlling driving circuits is supplied can be disposed. For example, the control signal can include various timing signals including a clock signal, an input data enable signal, and synchronization signals, but the example embodiments of the present disclosure are not limited thereto. The control signal can be received through the pad unit PAD. For example, in the non-active area NA, link lines LL can be disposed to transmit signals. For example, driving components, such as the flexible circuit board 400 and the printed circuit board 500, can be connected to the pad unit PAD.

According to the present disclosure, the non-active area NA can include a first non-active area NA1, a bending area BA, and a second non-active area NA2. For example, the first non-active area NA1 can be an area which encloses at least a part of the active area AA. The bending area BA is an area extending from at least one side, among a plurality of sides of the first non-active area NA1 and can be a bendable area. The second non-active area NA2 is an area extending from the bending area BA and the pad unit PAD can be disposed therein. For example, the bending area BA is in a bent state and the other areas of the substrate 110 excluding the bending area BA can be in a flat state. In this case, as the bending area BA is bent, the second non-active area NA2 can be located on a rear surface of the active area AA, but the example embodiments of the present disclosure are not limited thereto.

The active area AA of the substrate 110 or the display device 1000 can be configured with various shapes depending on a design of the display device 1000. For example, the active area can be configured with a rectangular shape formed with four rounded corners, but the example embodiments of the present disclosure are not limited thereto. As another example, the active area AA can be configured with a rectangular shape formed with four right-angled corners or a circular shape, but the example embodiments of the present disclosure are not limited thereto.

According to the present disclosure, a width of the second non-active area NA2 in which the plurality of pad electrodes PE is disposed can be larger than a width of the bending area BA in which only a plurality of link lines LL is disposed. Further, a width of the active area AA in which the plurality of sub pixels is disposed can be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

Referring to FIG. 3, a plurality of pixel driving circuits PD can be disposed in the active area AA. The plurality of pixel driving circuits PD can be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD can include a power line and a signal line for controlling emission on/off of the micro LED and/or an emission time. For example, the plurality of pixel driving circuits PD can be driving drives manufactured using a metal-oxide-silicon field effect transistor (MOSFET) manufacturing process on a semiconductor substrate, but the example embodiments of the present disclosure are not limited thereto. The driving driver includes a plurality of pixel driving circuits PD and can drive a plurality of sub pixels.

Referring to FIG. 1 together, the flexible circuit board 400 and the printed circuit board 500 can be disposed below the display panel 100. The flexible circuit board 400 and the printed circuit board 500 can be disposed at least at one edge of the display panel 100, but the example embodiments of the present disclosure are not limited thereto. One side of the flexible circuit board 400 is attached to the display panel 100 and the other side is attached to the printed circuit board 500, but the example embodiments of the present disclosure are not limited thereto. The flexible circuit board 400 can be a flexible film, but the example embodiments of the present disclosure are not limited thereto.

A pad unit PAD including a plurality of pad electrodes PE can be disposed in the second non-active area NA2. In the pad unit PAD, a driving component including one or more flexible circuit board (or a flexible film) 400 and the printed circuit board 500 can be attached or bonded. The plurality of pad electrodes PE of the pad unit PAD is electrically connected to one or more flexible circuit boards (or flexible films) 400 and can transmit various signals (or powers) from the printed circuit board 500 and the flexible circuit board (or a flexible film) 400 to the plurality of pixel driving circuits PD of the active area AA.

The flexible circuit board (or flexible film) 400 can be a film on which various components are disposed on a base film having ductility. For example, driving ICs such as a gate driver IC or a data driver IC can be disposed in the flexible circuit board (or flexible film) 400, but the example embodiments of the present disclosure are not limited thereto. The driving IC can be a component which processes data and driving signals to display images. The driving IC can be disposed by a chip on glass (COG), a chip on film (COF), or a tape carrier package (TCP) technique depending on a mounting method, but the example embodiments of the present disclosure are not limited thereto. The flexible circuit board (or flexible film) 400 can be attached or bonded onto the plurality of pad electrodes PE through a conductive adhesive layer, but the example embodiments of the present disclosure are not limited thereto.

The printed circuit board 500 can be a component which is electrically connected to one or more flexible circuit boards (or flexible films) 400 and supplies a signal to the driving IC. The printed circuit board 500 is disposed at one side of the flexible circuit board (or flexible film) 400 to be electrically connected to the flexible circuit board (or flexible film) 400. On the printed circuit board 500, various components for supplying various signals to the driving IC can be disposed. For example, on the printed circuit board 500, various components, such as a timing controller, a power source, a memory, or a processor, can be disposed. For example, the printed circuit board 500 can include a power management integrated circuit (PMIC), but the example embodiments of the present disclosure are not limited thereto.

The printed circuit board 500 can include at least one hole 510, but the example embodiments of the present disclosure are not limited thereto. An internal component which senses ambient light or temperature to be supplied to a plurality of sensors can be disposed in an area corresponding to at least one hole 510. For example, the internal component can include an ambient light sensor (ALS) or a temperature sensor, but the example embodiments of the present disclosure are not limited thereto. For example, the hole 510 can be a transmission hole, but the example embodiments of the present disclosure are not limited thereto.

Referring to FIG. 1, a polarization layer 293 can be disposed on the display panel 100. The polarization layer 293 can suppress or reduce the influence on the micro LED caused by light generated from an external light source and entering the display panel 100.

A cover member 200 can be disposed on the polarization layer 293. The cover member 200 can be a member for protecting the display panel 100. An adhesive layer 295 can be disposed between the polarization layer 293 and the cover member 200. The cover member 200 can be attached to the display panel 100 using the adhesive layer 295. The adhesive layer 295 can include an optically clear adhesive (OCA), an optically clear resin (OCR), or a pressure sensitive adhesive (PSA), but the example embodiments of the present disclosure are not limited thereto.

A support substrate 300 can be disposed between the display panel 100 and the printed circuit board 500. The support substrate 300 can reinforce a rigidity of the display panel 100. The support substrate 300 can be a back plate, but the example embodiments of the present disclosure are not limited thereto.

Referring to FIGS. 1 to 3, the plurality of link lines LL can be disposed in the non-active area NA. The plurality of link lines LL can be wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) 400 and the printed circuit board 500 through the driving line VL of the active area AA and the link line LL of the non-active area NA to be driven.

For example, the plurality of driving lines VL can be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 can be transmitted to each of the plurality of pixel driving circuits PD through the plurality of link lines LL and the plurality of driving lines VL.

As the bending area BA is bent, a part of the plurality of link lines LL is bent together. A stress is concentrated in the bent part of the link line LL, which causes a crack on the link line LL. Accordingly, the plurality of link lines LL can be configured by a conductive material having excellent ductility to reduce the crack caused when the bending area BA is bent. For example, the plurality of link lines LL can be configured by a conductive material having excellent ductility, such as gold (Au), silver (Ag), or aluminum (Al), but the example embodiments of the present disclosure are not limited thereto. Further, the plurality of link lines LL can be configured by one of various conductive materials used for the active area AA. For example, the plurality of link lines LL can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL can be configured by a multi-layered structure including various conductive materials. For example, the plurality of link lines LL can be configured with a triple layered structure of titanium (Ti)/aluminum (Al)/titanium (Ti), but the example embodiments of the present disclosure are not limited thereto.

The plurality of link lines LL can be configured with various shapes to reduce a stress. At least a part of the plurality of link lines LL disposed on the bending area BA can extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA can extend in an inclined direction from one direction. As another example, at least a part of the plurality of link lines LL can be configured by various shapes of patterns. For example, at least a part of the plurality of link lines LL disposed on the bending area BA can have a shape in which a conductive pattern having at least one shape of a diamond shape, a rhombus shape, a trapezoidal wave shape, a triangular wave shape, a sawtooth wave shape, a sine wave shape, a circular shape, an omega (£2) shape is repeatedly disposed. However, the example embodiments of the present disclosure are not limited thereto. Accordingly, in order to minimize a stress concentrated on the plurality of link lines LL and a crack caused thereby, a shape of the plurality of link lines LL can be various shapes including the above-mentioned shapes, but the example embodiments of the present disclosure are not limited thereto.

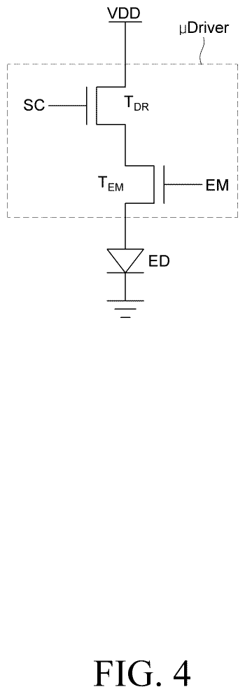

FIG. 4 is a view illustrating a circuit structure according to an example embodiment of the present disclosure.

A pixel driving circuit PD can include a micro driver (μDriver). The micro LED (ED) is electrically connected to the micro driver (μDriver) of the pixel driving circuit PD to be driven. Even though in FIG. 4, it is illustrated that one micro LED (ED) is connected to one micro driver (μDriver), but the present disclosure is not limited thereto. For example, eight micro LEDs (ED) can be connected to one micro driver (μDriver). As another example, 16 micro LEDs (ED) can be connected to one micro driver (μDriver) or 32 micro LEDs (ED) or 64 micro LED (ED) can be simultaneously connected to one micro driver (μDriver).

Referring to FIG. 4, one micro driver (μDriver) can include a driving transistor TDR and an emission transistor TEM, but the example embodiments of the present disclosure are not limited thereto.

For example, a high potential power voltage VDD is applied to a first electrode of the driving transistor TDR and a first electrode of the emission transistor TEM is connected to a second electrode, and a scan signal SC can be applied to a gate electrode. The scan signal SC applied to the gate electrode of the driving transistor TDR is a direct current (DC) power and a fixed reference voltage can be applied in every frame, but the example embodiments of the present disclosure are not limited thereto.

The second electrode of the driving transistor TDR is connected to a first electrode of the emission transistor TEM, the micro LED (ED) is connected to a second electrode, and the emission signal EM can be applied to a gate electrode. The emission signal EM applied to the gate electrode of the emission transistor TEM can be a pulse width modulation signal which changes in every frame, but the example embodiments of the present disclosure are not limited thereto.

A first electrode of the micro LED (ED) is connected to the second electrode of the emission transistor TEM and a second electrode can be connected to the ground. For example, the first electrode is an anode electrode and the second electrode can be a cathode electrode, but the example embodiments of the present disclosure are not limited thereto.

Each of the driving transistor TDR and the emission transistor TEM can be an n-type transistor or a p-type transistor.

The driving transistor TDR is turned on by a scan signal SC applied from the timing controller T-CON to the micro driver (μDriver) and the emission transistor TEM is turned on by the emission signal EM. By doing this, the driving current is applied to the micro LED (ED) via the driving transistor TDR and the emission transistor TEM by the high potential power voltage VDD applied to the first electrode of the driving transistor TDR so that the micro LED (ED) can emit light.

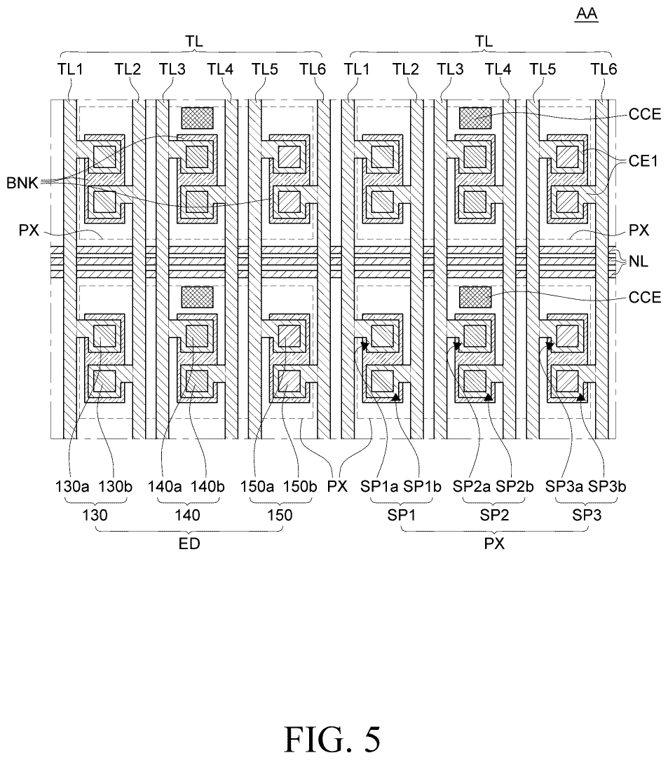

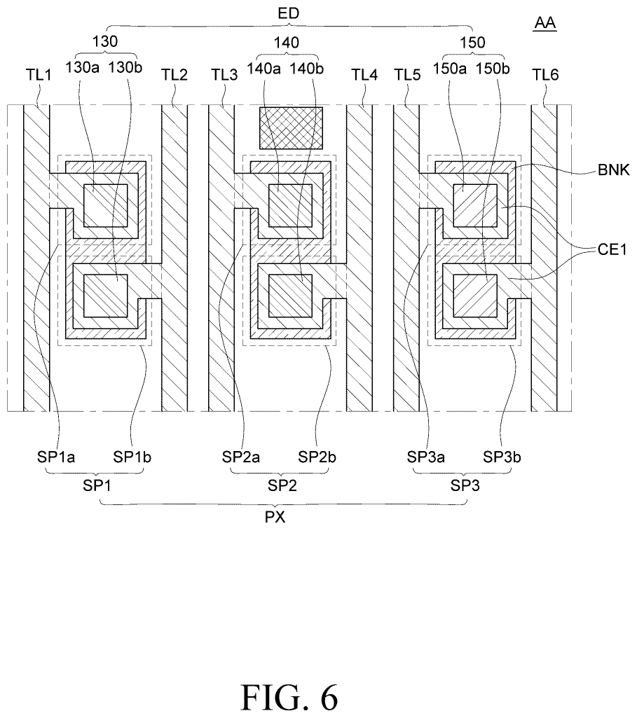

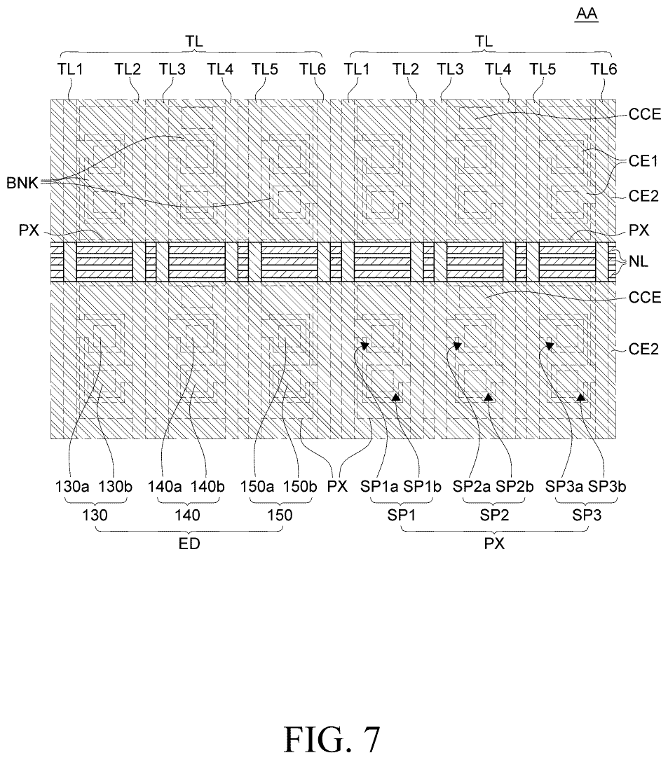

FIGS. 5 to 7 are plan views of a display device according to an example embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, a plurality of signal lines TL, a plurality of communication lines NL, a plurality of first electrodes CE1, a plurality of banks BNK, and a plurality of micro LEDs (ED) are illustrated, but the example embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels can be disposed in the active area AA. Each of the plurality of sub pixels includes a micro LED (ED) and can independently emit light. The plurality of sub pixels can be disposed in a matrix by forming a plurality of rows and a plurality of columns, but the example embodiments of the present disclosure are not limited thereto.

The plurality of sub pixels can include a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third can be a blue sub pixel. The types of the plurality of sub pixels are illustrative, but the example embodiments of the present disclosure are not limited thereto.

Each of the plurality of pixels PX can include one or more first sub pixels SP1, one or more second sub pixels SP2, and one or more third sub pixels SP3. For example, one pixel PX can include one pair of first sub pixels SP1, one pair of second sub pixels SP2, and one pair of third sub pixels SP3. One pair of first sub pixels SP1 can be configured by a 1-1-th sub pixel SP1a and a 1-2-th sub pixel SP1b. One pair of second sub pixels SP2 can be configured by a 2-1-th sub pixel SP2a and a 2-2-th sub pixel SP2b. One pair of third sub pixels SP3 can be configured by a 3-1-th sub pixel SP3a and a 3-2-th sub pixel SP3b. For example, one pixel PX can include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

The plurality of sub pixels which form one pixel PX can be disposed in various ways. For example, in one pixel PX, one pair of first sub pixels SP1 is disposed on the same column, one pair of second sub pixels SP2 is disposed on the same column, and one pair of third sub pixels SP3 can be disposed on the same column. The first sub pixels SP1, the second sub pixels SP2, and the third sub pixels SP3 can be disposed on the same row. A number and a placement of the plurality of sub pixels which configure one pixel PX are illustrative, but the example embodiments of the present disclosure are not limited thereto.

The plurality of signal lines TL can be disposed in an area between the plurality of sub pixels. The plurality of signal lines TL can extend in the column direction between the plurality of sub pixels. The plurality of signal lines TL can be wiring lines which transmit an anode voltage from the pixel driving circuit PD to the plurality of sub pixels. For example, the plurality of signal lines TL can be electrically connected to the plurality of pixel driving circuits PD and the first electrodes CE1 of the plurality of sub pixels. The anode voltage output from the pixel driving circuit PD can be transmitted to the first electrode CE1 of the plurality of sub pixels through the plurality of signal lines TL. For example, the first electrode CE1 can be an electrode which is electrically connected to the anode electrode 134 of the micro LED (ED). Therefore, the anode voltage from the signal line TL can be transmitted to the anode electrode 134 of the micro LED (ED) through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display device 1000. Further, a circuit which is disposed in each of the plurality of sub pixels is integrated in one pixel driving circuit PD so that highly efficient low power driving is possible.

The plurality of signal lines TL can include a first signal line TL1, a second signal line TL2, a third signal line TL3, a fourth signal line TL4, a fifth signal line TL5, and a sixth signal line TL6. The first signal line TL1 and the second signal line TL2 can be electrically connected to one pair of first sub pixels SP1, respectively. The third signal line TL3 and the fourth signal line TL4 can be electrically connected to one pair of second sub pixels SP2, respectively. The fifth signal line TL5 and the sixth signal line TL6 can be electrically connected to one pair of third sub pixels SP3, respectively.

The first signal line TL1 is disposed on one of one pair of first sub pixels SP1 and the second signal line TL2 can be disposed on the other one of one pair of first sub pixels SP1. The first signal line TL1 can be electrically connected to the first electrode CE1 of one first sub pixel SP1 of one pair of first sub pixels SP1, for example, the 1-1-th sub pixel SP1a. The second signal line TL2 can be electrically connected to the first electrode CE1 of the other first sub pixel SP1 of one pair of first sub pixels SP1, for example, the 1-2-th sub pixel SP1b.

The third signal line TL3 is disposed on one of one pair of second sub pixels SP2 and the fourth signal line TL4 can be disposed on the other one of one pair of second sub pixels SP2. For example, the third signal line TL3 can be disposed to be adjacent to the second signal line TL2. The third signal line TL3 can be electrically connected to the first electrode CE1 of one second sub pixel SP2 of one pair of second sub pixels SP2, for example, the 2-1-th sub pixel SP2a. The fourth signal line TL4 can be electrically connected to the first electrode CE1 of the other second sub pixel SP2 of one pair of second sub pixels SP2, for example, the 2-2-th sub pixel SP2b.

The fifth signal line TL5 is disposed on one of one pair of third sub pixels SP3 and the sixth signal line TL6 can be disposed on the other one of one pair of third sub pixels SP3. For example, the fifth signal line TL5 can be disposed to be adjacent to the fourth signal line TL4. The sixth signal line TL6 can be disposed to be adjacent to the first signal line TL1 connected to the adjacent pixel PX. The fifth signal line TL5 can be electrically connected to the first electrode CE1 of one third sub pixel SP3 of one pair of third sub pixels SP3, for example, the 3-1-th sub pixel SP3a. The sixth signal line TL6 can be electrically connected to the first electrode CE1 of the other third sub pixel SP3 of one pair of third sub pixels SP3, for example, the 3-2-th sub pixel SP3b.

The plurality of signal lines TL can be formed of a conductive material. For example, the plurality of signal lines TL can be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the plurality of signal lines TL can be formed with a multi-layered structure of conductive materials. For example, the plurality of signal lines TL can be formed with a multi-layered structure of titanium (Ti)/aluminum (Al)/titanium (Ti)/indium tin oxide (ITO), but the example embodiments of the present disclosure are not limited thereto.

A plurality of communication lines NL can be disposed in an area between the plurality of pixels PX. The plurality of communication lines NL can be disposed to extend in the row direction in an area between the plurality of pixels PX. The plurality of communication lines NL is disposed in the area between the plurality of second electrodes CE2 and does not overlap the plurality of second electrodes CE2. For example, the plurality of communication lines NL can be wiring lines used for short distance communication, such as near field communication (NFC). The plurality of communication lines NL can serve as antennas. For example, the plurality of communication lines NL can be a plurality of connection lines, but the example embodiments of the present disclosure are not limited thereto.

According to the present disclosure, a bank BNK can be disposed in each of the plurality of sub pixels. The plurality of banks BNK can be structures in which the plurality of micro LEDs (ED) is seated. The plurality of banks BNK can guide a position of the plurality of micro LEDs (ED) during a transfer process of transferring the plurality of micro LEDs (ED) to the display device 1000. The plurality of micro LEDs (ED) can be transferred onto the plurality of banks BNK in the transfer process of the plurality of micro LEDs (ED). The plurality of banks BNK can be a bank pattern or a structure, but the example embodiments of the present disclosure are not limited thereto.

A bank BNK of the first sub pixel SP1, a bank BNK of the second sub pixel SP2, and a bank BNK of the third sub pixel SP3 can be disposed to be spaced apart from each other. The bank BNK of the first sub pixel SP1, the bank BNK of the second sub pixel SP2, and the bank BNK of the third sub pixel SP3 can be configured to be separated from each other. Therefore, the banks BNK of the first sub pixel SP1, the second sub pixel SP2, and the third sub pixel SP3 to which different types of micro LEDs (ED) are transferred can be easily identified.

The bank BNK of the 1-1-th sub pixel SP1a and the bank BNK of the 1-2-th sub pixel SP1b can be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED (ED) is disposed can be connected to each other or spaced apart or separated from each other. Further, the bank BNK of the 2-1-th sub pixel SP2a and the bank BNK of the 2-2-th sub pixel SP2b can be connected to each other, spaced apart or separated from each other. The bank BNK of the 3-1-th sub pixel SP3a and the bank BNK of the 3-2-th sub pixel SP3b can be connected to each other, spaced apart or separated from each other. Accordingly, the banks BNK of one pair of first sub pixels SP1, the banks BNK of one pair of second sub pixels SP2, and the banks BNK of third sub pixels SP3 are formed in various forms, but the example embodiments of the present disclosure are not limited thereto.

For example, the plurality of banks BNK can be formed of an organic insulating material. The plurality of banks BNK is configured by a single layer or a double layer of an organic insulating material. For example, the plurality of banks BNK is configured by a photo resist, polyimide (PI), or acrylic-based material, but the example embodiments of the present disclosure are not limited thereto.

The first electrode CE1 can be disposed in each of the plurality of sub pixels. The first electrode CE1 can be disposed on the bank BNK. The first electrode CE1 can be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 is electrically connected to the anode electrode 134 of the micro LED (ED) and can transmit an anode voltage from the pixel driving circuit PD to the micro LED (ED) through the signal line TL. Different voltages can be applied to the first electrodes CE1 of the plurality of sub pixels depending on the image to be displayed. For example, different voltages can be applied to the first electrodes CE1 of the plurality of sub pixels. Therefore, the first electrode CE1 can be a pixel electrode, but the example embodiments of the present disclosure are not limited thereto.

The first electrode CE1 can be configured by a conductive material. For example, the first electrode CE1 can be integrally configured with the plurality of signal lines TL. For example, the first electrode CE1 can be configured by the same conductive material as the plurality of signal lines TL, but the example embodiments of the present disclosure are not limited thereto. For example, the first electrode CE1 can be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the first electrode CE1 can be configured by a multi-layered structure of conductive materials. For example, the plurality of first electrodes CE1 can be configured by a multi-layered structure of titanium (Ti)/aluminum (Al)/titanium (Ti)/indium tin oxide (ITO), but the example embodiments of the present disclosure are not limited thereto.

The micro LED (ED) can be disposed in each of the plurality of sub pixels. The plurality of micro LEDs (ED) can be disposed on the bank BNK and the first electrode CE1. The plurality of micro LEDs (ED) is disposed on the first electrode CE1 and is electrically connected to the first electrode CE1. Accordingly, the micro LED (ED) is applied with an anode voltage from the pixel driving circuit PD through the signal line TL and the first electrode CE1 to emit light.

The plurality of micro LEDs (ED) can include a first micro LED 130, a second micro LED 140, and a third micro LED 150. The first micro LED 130 can be disposed in the first sub pixel SP1. The second micro LED 140 can be disposed in the second sub pixel SP2. The third micro LED 150 can be disposed in the third sub pixel SP3. For example, any one of the first micro LED 130, the second micro LED 140, and the third micro LED 150 is a red micro LED, another is a green micro LED, and the third is a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The first micro LED 130 can include a 1-1-th micro LED 130a disposed in the 1-1-th sub pixel SP1a and a 1-2-th micro LED 130b disposed in the 1-2-th sub pixel SP1b. The second micro LED 140 can include a 2-1-th micro LED 140a disposed in the 2-1-th sub pixel SP2a and a 2-2-th micro LED 140b disposed in the 2-2-th sub pixel SP2b. The third micro LED 150 includes a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 can be disposed in each of the plurality of sub pixels. The second electrode CE2 can be disposed on the micro LED (ED). The second electrode CE2 can be electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage can be applied to the second electrodes CE2 of the plurality of sub pixels. For example, the same voltage can be applied to the second electrode CE2 of each of the plurality of sub pixels and the cathode electrode 135 of the micro LED (ED). Therefore, the second electrode CE2 can be a common electrode, but the example embodiments of the present disclosure are not limited thereto.

At least some of the plurality of sub pixel can share the second electrode CE2. At least some of the second electrodes CE2 of the plurality of sub pixels can be electrically connected to each other. As the same voltage is applied to the second electrode CE2, the second electrodes CE2 of at least some of sub pixels are shared. For example, the second electrodes of at least some pixels PX, among the plurality of pixels PX disposed on the same row can be connected to each other. For example, one second electrode CE2 can be disposed in the plurality of pixels PX. One second electrode CE2 can be disposed in every n sub pixels.

For example, some of the second electrodes CE2 of the plurality of sub pixels can be spaced apart or separated from each other. For example, a second electrode CE2 connected to pixels PX in a n-th row and a second electrode CE2 connected to pixels PX in a n+1-th row can be spaced apart or separated from each other. For example, the plurality of second electrodes CE2 can be disposed to be spaced apart from each other with the plurality of communication lines NL extending in the row direction therebetween. Accordingly, the number of the plurality of sub pixels can be larger than the number of the plurality of second electrodes CE2. As another example, all the second electrodes CE2 of the plurality of sub pixels are connected to each other so that only one second electrode CE2 can be disposed on the substrate 110, but the example embodiments of the present disclosure are not limited thereto.

The plurality of second electrodes CE2 can be configured by a transparent conductive material, but the example embodiments of the present disclosure are not limited thereto. The plurality of second electrodes CE2 is configured by a transparent conductive material so that light emitted from the micro LED (ED) can travel toward the top of the second electrode CE2. For example, the second electrode CE2 can be configured by a transparent conductive material, such as indium tin oxide (ITO), indium zinc oxide (IZO), indium gallium zinc oxide (IGZO), but the example embodiments of the present disclosure are not limited thereto.

A plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap at least one contact electrode CCE. For example, one second electrode CE2 can overlap a plurality of contact electrodes CCE.

For example, the plurality of contact electrodes CCE can be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

Referring to FIG. 7, the black matrix BM is disposed on the plurality of second electrodes CE2. The black matrix BM can minimize the color mixture of the light of the plurality of sub pixels. The black matrix BM can be formed of an opaque material. For example, the black matrix BM can be an organic insulating material to which a black pigment is added.

A black matrix BM includes a plurality of transmission holes. The plurality of transmission holes is openings which overlap micro LEDs (ED) of a plurality of sub pixels. Light emitted from the plurality of micro LEDs (ED) is extracted to the outside of the display panel 100 through the plurality of transmission holes. The plurality of transmission holes is disposed so as to overlap some sub pixel of the plurality of sub pixels included in one pixel PX.

The plurality of transmission holes is larger than the plurality of micro LEDs (ED). For example, on the plane, the plurality of transmission holes is formed to be wider than the plurality of micro LEDs (ED) to ensure a margin for a process deviation.

A planar shape of the plurality of transmission holes can correspond to a planar shape of the plurality of micro LEDs (ED). For example, when the planar shape of the plurality of micro LEDs (ED) is a rectangle, the planar shape of the plurality of transmission holes can be a rectangle. However, the planar shape of the plurality of transmission holes and the planar shape of the plurality of micro LEDs (ED) can be different from each other, but are not limited thereto.

In the meantime, when the micro LED (ED) is used, a plurality of micro LEDs is formed on a wafer and the micro LED is transferred onto the substrate 110 of the display panel 100 to manufacture the display panel 100. However, during the process of transferring the plurality of micro LEDs (ED) having a micro size from the wafer to the substrate 110, various defects can be caused. For example, in some sub pixel, a non-transfer defect in which the micro LED is not transferred can occur and in the other sub pixel, a defect that the micro LED (ED) is transferred in a wrong position can occur due to the alignment error. Further, even though the transfer process is normally performed, the transferred micro LED (ED) can be defective. Accordingly, in consideration of the defects for the transfer process of the plurality of micro LEDs (ED), a plurality of same type micro LEDs can be transferred in one sub pixel. Further, the lighting test for the plurality of micro LEDs (ED) is performed and only one micro LED (ED) which is finally determined to be normal can be used.

For example, the 1-1-th micro LED 130a and the 1-2-th micro LED 130b are transferred to one pixel PX together and defects thereof can be tested. If both the 1-1-th micro LED 130a and the 1-2-th micro LED 130b are determined to be normal, only the 1-1-th micro LED 130a is used, but the 1-2-th micro LED 130b is not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b can be used. Accordingly, even though the plurality of same type micro LEDs (ED) is transferred to one pixel PX, finally, only one micro LED (ED) can be used.

Therefore, any one of one pair of micro LEDs (ED) is a main (or primary) micro LED (ED) and the other micro LED (ED) can be a redundancy micro LED (ED). The redundancy micro LED (ED) can be an extra micro LED (ED) which is transferred to prepare for a defect of the main micro LED (ED). When the main micro LED (ED) is defective, the redundancy micro LED (ED) can be used instead. Accordingly, the main micro LED (ED) and the redundancy micro LED (ED) are transferred together to one pixel PX so that the degradation of the display quality due to the defects of the main micro LED (ED) and the redundancy micro LED (ED) can be minimized.

For example, a 1-1-th micro LED 130a, a 2-1-th micro LED 140a, and a 3-1-th micro LED 150a which are transferred to one pixel PX are used as main micro LEDs (ED) and a 1-2-th micro LED 130b, a 2-2-th micro LED 140b, and a 3-2-th micro LED 150b can be used as redundancy micro LEDs (ED).

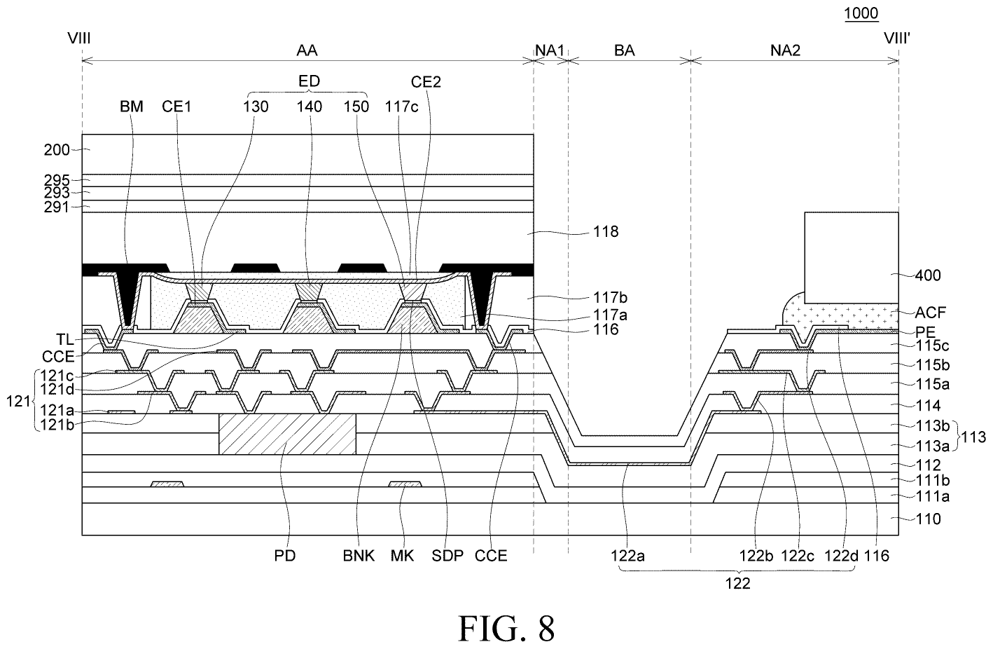

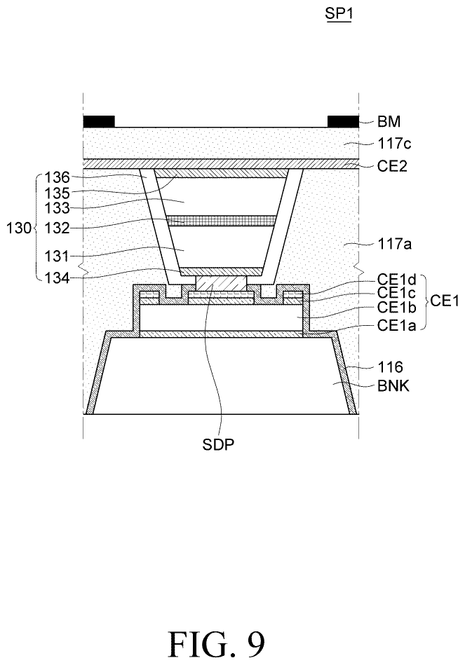

Hereinafter, a cross-sectional structure of a sub pixel of the display panel 100 according to the example embodiment of the present disclosure will be described with reference to FIGS. 8 and 9.

FIG. 8 is a cross-sectional view of a display device according to an example embodiment of the present disclosure. FIG. 9 is a cross-sectional view of a display device according to an example embodiment of the present disclosure. For example, FIG. 8 is a cross-sectional view taken along VIII-VIII′ of FIG. 3 which is a cross-sectional view of an active area AA, a first non-active area NA1, a bending area BA, and a second non-active area NA2. For example, FIG. 9 is an enlarged cross-sectional view of a first sub pixel.

Referring to FIG. 8, a first buffer layer 111a and a second buffer layer 111b can be disposed in the remaining area of the substrate 110 excluding the bending area BA.

The first buffer layer 111a and the second buffer layer 111b can be disposed in the active area AA, the first non-active area NA1, and the second non-active area NA2. The first buffer layer 111a and the second buffer layer 111b can reduce permeation of moisture or impurities through the substrate 110. The first buffer layer 111a and the second buffer layer 111b can be formed of an inorganic insulating material. For example, the first buffer layer 111a and the second buffer layer 111b can be configured by a single layer or a plurality of layers of silicon oxide (SiOx) or silicon nitride (SiNx), but the example embodiments of the present disclosure are not limited thereto.

For example, the first buffer layer 111a and the second buffer layer 111b on the bending area BA can be partially removed. A top surface of the substrate 110 located in the bending area BA can be exposed from the first buffer layer 111a and the second buffer layer 111b. The first buffer layer 111a and the second buffer layer 111b which are formed of an inorganic insulating material are removed from the bending area BA to minimize cracks of the first buffer layer 111a and the second buffer layer 111b which can be generated during the bending.

A plurality of alignment keys MK can be disposed between the first buffer layer 111a and the second buffer layer 111b. The plurality of alignment keys MK can be configured to identify a position of the pixel driving circuit PD during the manufacturing process of the display device 1000. For example, the plurality of alignment keys MK can be configured to align a position of the pixel driving circuit PD which is transferred onto the adhesive layer 112. As another example, the plurality of alignment keys MK can be omitted.

The adhesive layer 112 can be disposed on the second buffer layer 111b. The adhesive layer 112 can be disposed in the active area AA, the first non-active area NA1, the bending area BA, and the second non-active area NA2. As another example, in the non-active area NA including the bending area BA, at least a part of the adhesive layer 112 can be removed. For example, the adhesive layer 112 can be formed of any one of adhesive polymer, epoxy resin, UV curable resin, polyimide based, acrylate based, urethane based, and polydimethylsiloxane (PDMS), but the example embodiments of the present disclosure are not limited thereto.

The pixel driving circuit PD can be disposed on the adhesive layer 112 in the active area AA. When the pixel driving circuit PD is implemented as a driving driver, the driving driver can be mounted on the adhesive layer 112 by the transfer process, but the example embodiments of the present disclosure are not limited thereto.

A protection layer 113 can be disposed on the adhesive layer 112 and the pixel driving circuit PD. The protection layer 113 can be disposed so as to enclose the pixel driving circuit PD, but the example embodiments of the present disclosure are not limited thereto. For example, the protection layer 113 can be disposed so as to cover at least a part of a side surface of the pixel driving circuit PD. As another example, the protection layer 113 can be disposed so as to cover at least a part of a top surface of the pixel driving circuit PD.

The protection layer 113 can include one or more organic insulating layers. For example, the protection layer 113 can include a first protection layer 113a disposed on the adhesive layer 112 and a second protection layer 113b disposed on the first protection layer 113a. For example, the first protection layer 113a and the second protection layer 113b can be disposed so as to enclose a side surface of the pixel driving circuit PD. For example, the second protection layer 113b can be disposed so as to cover at least a part of a top surface of the pixel driving circuit PD. For example, at least one of the first protection layer 113a and the second protection layer 113b of the protection layer 113 disposed on the bending area BA can be omitted. For example, the first protection layer 113a is entirely disposed in the active area AA and the non-active area NA and the second protection layer 113b can be partially disposed in the active area AA, the first non-active area NA1, and the second non-active area NA2. For example, a part of the second protection layer 113b in the bending area BA can be removed. However, the protection layer 113 can be formed by a single layer, but the example embodiments of the present disclosure are not limited thereto.

Each of the first protection layer 113a and the second protection layer 113b of the protection layer can be configured by an organic insulating material, but the example embodiments of the present disclosure are not limited thereto. For example, the first protection layer 113a and the second protection layer 113b can be configured by a photo resist, polyimide (PI), or photo acrylic-based material, but the example embodiments of the present disclosure are not limited thereto. For example, the first protection layer 113a and the second protection layer 113b can be an over coating layer or an insulating layer, but the example embodiments of the present disclosure are not limited thereto.

According to the present disclosure, in the active area AA, the plurality of first connection lines 121 can be disposed on the second protection layer 113b. The plurality of first connection lines 121 can be wiring lines which electrically connect the pixel driving circuit PD to the other component. For example, the pixel driving circuit PD can be electrically connected to the plurality of signal lines TL and the plurality of contact electrodes CCE through the plurality of first connection lines 121. For example, the plurality of first connection lines 121 can include a 1-1-th connection line 121a, a 1-2-th connection line 121b, a 1-3-th connection line 121c, and a 1-4-th connection line 121d, but the example embodiments of the present disclosure are not limited thereto.

For example, the plurality of 1-1-th connection lines 121a can be disposed on the second protection layer 113b. The plurality of 1-1-th connection lines 121a can be electrically connected to the pixel driving circuit PD. The plurality of 1-1-th connection lines 121a can transmit a voltage output from the pixel driving circuit PD to the first electrode CE1 or the second electrode CE2.

For example, an additional protection layer can be further disposed on the second protection layer 113b. For example, a third protection layer 114 can be further disposed on the second protection layer 113b. The third planarization layer 114 can be entirely disposed in the active area AA and the non-active area NA. In the bending area BA, the third protection layer 114 can cover a side surface of the second protection layer 113b and the top surface of the first protection layer 113a. The third protection layer 114 can be configured by an organic insulating material. For example, the third protection layer 114 can be configured by a photo resist, polyimide (PI), or photo acrylic-based material, but the example embodiments of the present disclosure are not limited thereto. For example, the first protection layer 113a, the second protection layer 113b, and the third protection layer 114 can be configured by the same material, but the example embodiments of the present disclosure are not limited thereto.

The plurality of 1-2-th connection lines 121b can be disposed on the third protection layer 114. The plurality of 1-2-th connection lines 121b can be indirectly or directly connected to the pixel driving circuit PD. For example, a part of the 1-2-th connection line 121b can be directly connected to the pixel driving circuit PD through a contact hole of the third protection layer 114. The other part of the 1-2-th connection line 121b can be electrically connected to the 1-1-th connection line 121a through the contact hole of the third protection layer 114. However, the example embodiments of the present disclosure are not limited thereto. A voltage output from the pixel driving circuit PD can be transmitted to the first electrode CEL or the second electrode CE2 through a connection line other than the plurality of 1-2-th connection lines 121b.

The first insulating layer 115a can be disposed on the plurality of 1-2-th connection lines 121b. The first insulating layer 115a can be entirely disposed in the active area AA and the non-active area NA, but the example embodiments of the present disclosure are not limited thereto. The first insulating layer 115a can be configured by an organic insulating material, but the example embodiments of the present disclosure are not limited thereto. For example, the first insulating layer 115a can be configured by a photo resist, polyimide (PI), or photo acrylic-based material, but the example embodiments of the present disclosure are not limited thereto.

The plurality of 1-3-th connection lines 121c can be disposed on the first insulating layer 115a. The plurality of 1-3-th connection lines 121c can be electrically connected to the plurality of 1-2-th connection lines 121b. For example, the 1-3-th connection lines 121c can be electrically connected to the 1-2-th connection line 121b through a contact hole of the first insulating layer 115a.

The second insulating layer 115b can be disposed on the plurality of 1-3-th connection lines 121c. The second insulating layer 115b can be disposed in a remaining area excluding the bending area BA, but the example embodiments of the present disclosure are not limited thereto. The second insulating layer 115b can be disposed in the active area AA, the first non-active area NA1, and the second non-active area NA2, but the example embodiments of the present disclosure are not limited thereto. For example, a part of the second insulating layer 115b disposed in the bending area BA can be removed. The second insulating layer 115b can be configured by an organic insulating material, but the example embodiments of the present disclosure are not limited thereto. For example, the second insulating layer 115b is configured by a photo resist, polyimide (PI), or photo acrylic-based material, but the example embodiments of the present disclosure are not limited thereto.

The plurality of 1-4-th connection lines 121d can be disposed on the second insulating layer 115b. The plurality of 1-4-th connection lines 121d can be electrically connected to the plurality of 1-3-th connection lines 121c. For example, the 1-4-th connection lines 121d can be electrically connected to the 1-3-th connection line 121c through a contact hole of the second insulating layer 115b.

According to the present disclosure, in the non-active area NA, the plurality of second connection lines 122 can be disposed on the second protection layer 113b. The plurality of second connection lines 122 can be wiring lines which transmit a signal transmitted from the flexible circuit board (or flexible film) 400 and the printed circuit board 160 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board.

For example, the plurality of second connection lines 122 extends toward the active area AA from the pad unit PAD to transmit a signal to the wiring line of the active area AA. In this case, the plurality of second connection lines 122 can serve as a link line LL. The plurality of second connection lines 122 can include a 2-1-th connection lines 122a, a 2-2-th connection lines 122b, a 2-3-th connection lines 122c, and a 2-4-th connection lines 122d.

The plurality of 2-1-th connection lines 122a can be disposed on the second protection layer 113b. The plurality of 2-1-th connection lines 122a can extend from the second non-active area NA2 to the bending area BA and the first non-active area NA1. The plurality of 2-1-th connection lines 122a can transmit a signal transmitted from the flexible circuit board (or flexible film) 400 and the printed circuit board 500 to the pad unit PAD to the pixel driving circuit PD of the active area AA. For example, the 2-1-th connection line 122a extends from the second non-active area NA2 to the first non-active area NA1 and can be electrically connected to any one of the 1-1-th connection line 121a, the 1-2-th connection line 121b, the 1-3-th connection line 121c, and the 1-4-th connection line 121d of the plurality of first connection lines 121. For example, the 2-1-th connection line 122a can be directly connected to the 1-1-th connection line 121a disposed on the same layer or can be connected to the 1-2-th connection line 121b disposed on a different layer through a contact hole of the third protection layer 114, but is not limited thereto.

The plurality of 2-2-th connection lines 122b can be disposed on the third protection layer 114. The plurality of 2-2-th connection lines 122b can be disposed in the second non-active area NA2. The 2-2-th connection line 122b can be electrically connected to the 2-1-th connection line 122a through the contact hole of the third protection layer 114. Accordingly, a signal from the flexible circuit board (or flexible film) 400 and the printed circuit board can be transmitted to the 2-1-th connection line 122a through the 2-2-th connection line 122b.

The 2-3-th connection lines 122c can be disposed on the first insulating layer 115a. The 2-3-th connection lines 122c can be disposed in the second non-active area NA2. The 2-3-th connection lines 122c can be electrically connected to the 2-2-th connection line 122b through a contact hole of the first insulating layer 115a. Accordingly, a signal from the flexible circuit board (or flexible film) 400 and the printed circuit board can be transmitted to the 2-1-th connection line 122a through the 2-3-th connection line 122c and the 2-2-th connection line 122b.

The 2-4-th connection lines 122d can be disposed on the second insulating layer 115b. The 2-4-th connection lines 122d can be disposed in the second non-active area NA2. The 2-4-th connection lines 122d can be electrically connected to the 2-3-th connection line 122c through a contact hole of the second insulating layer 115b. Accordingly, a signal from the flexible circuit board (or flexible film) 400 and the printed circuit board 500 can be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 can be formed of any one of a conductive material having excellent ductility or various conductive materials used for the active area AA. For example, the second connection line 122 which is partially disposed in the bending area BA can be configured by a conductive material having excellent ductility, such as gold (Au), silver (Ag), or aluminum (Al), but the example embodiments of the present disclosure are not limited thereto. As another example, the plurality of first connection lines 121 and the plurality of second connection lines 122 can be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c can be disposed on the plurality of first connection lines 121 and the plurality of second connection lines 122. The third insulating layer 115c can be disposed in a remaining area excluding the bending area BA, but the example embodiments of the present disclosure are not limited thereto. The third insulating layer 115c can be disposed in the active area AA, the first non-active area NA1, and the second non-active area NA2. A part of the third insulating layer 115c disposed in the bending area BA can be removed. The third insulating layer 115c can be configured by an organic insulating material, but the example embodiments of the present disclosure are not limited thereto. For example, the third insulating layer 115c can be configured by a photo resist, polyimide (PI), or photo acrylic-based material, but the example embodiments of the present disclosure are not limited thereto.

A plurality of banks BNK can be disposed on the third insulating layer 115c in the active area AA. The plurality of banks BNK can be disposed so as to overlap each of the plurality of sub pixels. One or more same type micro LED (ED) can be disposed above each of the plurality of banks BNK.

A plurality of signal lines TL can be disposed on the third insulating layer 115c in the active area AA. The plurality of signal lines TL can be disposed in an area between the plurality of banks BNK. For example, the plurality of signal lines TL can be disposed to be adjacent to any one of the plurality of banks BNK.

A plurality of contact electrodes CCE can be disposed on the third insulating layer 115c in the active area AA. The plurality of contact electrodes CCE can supply a cathode voltage from the pixel driving circuit PD to the second electrode CE2.

The first electrode CE1 can be disposed on the bank BNK. For example, the first electrode CE1 can be disposed to extend toward the top of the bank BNK from the adjacent signal line TL. The first electrode CE1 can be disposed on the top surface of the bank BNK and the side surface of the bank BNK. For example, the first electrode CE1 can be disposed to extend from the signal line TL on the top surface of the third insulating layer 115c to the side surface of the bank BNK and the top surface of the bank BNK.

Referring to FIG. 9, the first electrode CE1 can be configured by a plurality of conductive layers. For example, the first electrode CE1 can include a first conductive layer CE1a, a second conductive layer CE1b, a third conductive layer CE1c, and a fourth conductive layer CE1d, but the example embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, the first conductive layer CE1a, the second conductive layer CE1b, the third conductive layer CE1c, and the fourth conductive layer CE1d can be configured by titanium (Ti), molybdenum (Mo), aluminum (Al), or titanium (Ti) and indium tin oxide (ITO), but the example embodiments of the present disclosure are not limited thereto.

According to the present disclosure, some conductive layer having a good reflection efficiency, among a plurality of conductive layers which configure the first electrode CE1 can be configured as an alignment key for alignment of the micro LED (ED) and/or a reflective plate. For example, the second conductive layer CE1b, among the plurality of conductive layers of the first electrode CE1, can include a reflective material. For example, the second conductive layer CE1b can include aluminum (Al), but the example embodiments of the present disclosure are not limited thereto. Therefore, the second conductive layer CE1b can be configured as a reflective plate. Further, the second conductive layer CE1b has a high reflection efficiency to be easily identified during the manufacturing process so that a position of the micro LED (ED) or a transfer position can be aligned based on the second conductive layer CE1b.

For example, in order to configure the second conductive layer CE1b as a reflective plate, the third conductive layer CE1c and the fourth conductive layer CE1d which cover the second conductive layer CE1b can be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remains and the remaining portion excluding the portions can be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 can be suppressed.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which is adhesive to the solder pattern SPD, and has corrosion resistance and acid resistance. However, the example embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the example embodiments of the present disclosure are not limited thereto.

According to the present disclosure, the signal line TL, the contact electrode CCE, and the pad electrode PE disposed on the same layer as the first electrode CE1 can be configured by a plurality of layers of conductive materials, but the example embodiment of the present disclosure are not limited thereto. For example, the signal line TL, the contact electrode CCE, and the pad electrode PE can be formed of a plurality of layers of indium tin oxide (ITO)/titanium (Ti)/aluminum (Al)/titanium (Ti), but the example embodiments of the present disclosure are not limited thereto.

According to the present disclosure, in each of the plurality of sub pixels, the solder pattern SDP can be disposed on the first electrode CE1. The solder pattern SDP can bond the micro LED (ED) to the first electrode CE1. The solder pattern SDP can bond the first electrode CE1 and the anode electrode 134 of the micro LED (ED) to be electrically connected to each other. The first electrode CE1 and the micro LED (ED) can be electrically connected through eutectic bonding using the solder pattern SDP, but the example embodiments of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) can be bonded to the solder pattern SDP and the first electrode CE1 using the eutectic bonding without a separate adhesive material. For example, the solder pattern SDP can be configured by indium (Id), tin (Sn), or an alloy thereof, but the example embodiments of the present disclosure are not limited thereto. For example, the solder pattern SDP can be a bonding pad or an adhesive pad, but the example embodiments of the present disclosure are not limited thereto.

According to the present disclosure, the passivation layer 116 can be disposed on the plurality of signal lines TL, the plurality of first electrodes CE1, the plurality of contact electrodes CCE, and the third insulating layer 115c. For example, the passivation layer 116 can be disposed in the active area AA, the first non-active area NA1, and the second non-active area NA2. A part of the passivation layer 116 disposed in the bending area BA can be removed. A part of the passivation layer 116 which covers a plurality of pad electrodes PE in the second non-active area NA2 can be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 can be configured by a single layer or a plurality of layers of silicon oxide (SiOx) or silicon nitride (SiNx), but the example embodiments of the present disclosure are not limited thereto. For example, the passivation layer 116 can be a protection layer or an insulating layer, but the example embodiments of the present disclosure are not limited thereto. For example, the passivation layer 116 can include a hole through which the solder pattern SDP is exposed.

In each of the plurality of sub pixels, the micro LED (ED) can be disposed on the solder pattern SDP. A first micro LED 130 can be disposed in the first sub pixel SP1. A second micro LED 140 can be disposed in the second sub pixel SP2. A third micro LED 150 can be disposed in the third sub pixel SP3.

The micro LED (ED) can be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the example embodiments of the present disclosure are not limited thereto.

Referring to FIG. 9, the first micro LED 130 can include an anode electrode 134, a first semiconductor layer 131, an active layer 132, a second semiconductor layer 133, a cathode electrode 135, and an encapsulation film 136, but the example embodiments of the present disclosure are not limited thereto. For example, the encapsulation film 136 may not be included in the first micro LED 130.

The first semiconductor layer 131 can be disposed on the solder pattern SDP. The second semiconductor layer 133 can be disposed on the first semiconductor layer 131.

For example, one of the first semiconductor layer 131 and the second semiconductor layer 133 can be implemented by a compound semiconductor, such as a III-V group or a II-VI group and can be doped with an impurity (or dopant). For example, one of the first semiconductor layer 131 and the second semiconductor layer 133 is an n-type impurity doped semiconductor layer and the other one is a p-type impurity doped semiconductor, but the example embodiments of the present disclosure are not limited thereto. For example, one or more of the first semiconductor layer 131 and the second semiconductor layer 133 can be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity can be silicon (Si), germanium (Ge), selenium (Se), carbon (C), tellurium (Te), or tin (Sn), but the example embodiments of the present disclosure are not limited thereto. For example, the p-type impurity can be magnesium (Mg), zinc (Zn), calcium (Ca), strontium (Sr), barium (Ba), or beryllium (Be), but the example embodiments of the present disclosure are not limited thereto.

For example, each the first semiconductor layer 131 and the second semiconductor layer 133 can be a nitride semiconductor including an n-type impurity or a nitride semiconductor including a p-type impurity, but the example embodiments of the present disclosure are not limited thereto. For example, the first semiconductor layer 131 can be a nitride semiconductor including a p-type impurity and the second semiconductor layer 133 can be a nitride semiconductor including an n-type impurity, but the example embodiments of the present disclosure are not limited thereto.

The active layer 132 can be disposed between the first semiconductor layer 131 and the second semiconductor layer 133. The active layer 132 is supplied with holes and electrons from the first semiconductor layer 131 and the second semiconductor layer 133 to emit light. For example, the active layer 132 can be configured by one of a single well structure, a multi-well structure, a signal quantum well structure, a multi-quantum well (MQC) structure, a quantum dot structure, and a quantum line structure, but the example embodiments of the present disclosure are not limited thereto. For example, the active layer 132 can be configured by indium gallium nitride (InGaN) or gallium nitride (GaN), but the example embodiments of the present disclosure are not limited thereto.

As another example, the active layer 132 has a multi quantum well (MQW) structure having a well layer and a barrier layer with a band gap higher than the well layer. For example, in the active layer 132, InGaN is configured as a well layer and an AlGaN layer is configured as a barrier layer, but the example embodiments of the present disclosure are not limited thereto.

The anode electrode 134 can be disposed between the first semiconductor layer 131 and the solder pattern SDP. For example, the anode electrode 134 can electrically connect the first semiconductor layer 131 and the first electrode CE1. The anode voltage output from the pixel driving circuit PD can be applied to the first semiconductor layer 131 through the signal line TL, the first electrode CE1, and the anode electrode 134. For example, the anode electrode 134 can be configured by a conductive material which can form eutectic bonding with the solder pattern SDP, but the example embodiments of the present disclosure are not limited thereto. For example, the anode electrode 134 can be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 can be disposed on the second semiconductor layer 133. For example, the cathode electrode 135 can electrically connect the second semiconductor layer 133 and the second electrode CE2. A cathode voltage output from the pixel driving circuit PD can be applied to the second semiconductor layer 133 through the contact electrode CCE, the second electrode CE2, and the cathode electrode 135. The cathode electrode 135 can be configured by a transparent conductive material to allow light emitted from the micro LED (ED) to be directed to the top of the micro LED (ED), but the example embodiments of the present disclosure are not limited thereto. For example, the cathode electrode 135 can be configured by a material, such as indium tin oxide (ITO), indium zinc oxide (IZO), indium gallium zinc oxide (IGZO), but the example embodiments of the present disclosure are not limited thereto.

The encapsulation film 136 can be disposed in at least a part of the first semiconductor layer 131, the active layer 132, the second semiconductor layer 133, the anode electrode 134, and the cathode electrode 135. For example, the encapsulation film 136 can enclose at least a part of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on a side surface of the first semiconductor layer 131, a side surface of the active layer 132, and a side surface of the second semiconductor layer 133.

For example, the encapsulation film 136 can be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP can be connected. For example, at least a part of the cathode electrode 135 is exposed from the encapsulation film 136 so that the cathode electrode 135 and the second electrode CE2 can be connected. For example, the encapsulation film 136 can be formed of an insulating material, such as silicon nitride (SiNx) or silicon oxide (SiOx), but the example embodiments of the present disclosure are not limited thereto.

As another example, the encapsulation film 136 can have a structure in which a reflective material is dispersed in a resin layer, but the example embodiments of the present disclosure are not limited thereto. For example, the encapsulation film 136 can be manufactured with reflectors with various structures, but the example embodiments of the present disclosure are not limited thereto. Light emitted from the active layer 132 is upwardly reflected by the encapsulation film 136 so that light extraction efficiency can be improved. For example, the encapsulation film 136 can be a reflective layer, but the example embodiments of the present disclosure are not limited thereto.

According to the present disclosure, it is described that the micro LED (ED) has a vertical structure, but the example embodiments of the present disclosure are not limited thereto. For example, the micro LED (ED) can have a lateral structure or a flip-chip structure.

The first micro LED 130 has been described with reference to FIG. 9 and the second micro LED 140 and the third micro LED 150 can have the substantially same structure as the first micro LED 130. For example, the second micro LED 140 and the third micro LED 150 can be substantially the same as the first semiconductor layer 131, the active layer 132, the second semiconductor layer 133, the anode electrode 134, the cathode electrode 135, and the encapsulation film 136 of the first micro LED 130.

According to the present disclosure, in the active area AA, a first optical layer 117a which encloses the plurality of micro LEDs (ED) can be disposed. For example, the first optical layer 117a can be disposed so as to cover the plurality of micro LEDs (ED) and the bank BNK in the area of the plurality of sub pixels. For example, the first optical layer 117a can cover the bank BNK, a part of the passivation layer 116 and between the plurality of micro LEDs (ED). The first optical layer 117a can be disposed or cover between the plurality of micro LEDs (ED) and between the plurality of banks BNK included in one pixel PX. For example, the first optical layer 117a extends in a row direction and can be spaced apart from each other in a column direction. For example, the first optical layer 117a can be disposed so as to enclose side portions of the micro LED (ED) and the bank BNK between the passivation layer 116 and the second electrode CE2, but the example embodiments of the present disclosure are not limited thereto. For example, the first optical layer 117a can be a diffusion layer or a side wall diffusion layer, but the example embodiments of the present disclosure are not limited thereto.

The first optical layer 117a can include an organic insulating material in which micro particles are dispersed, but the example embodiments of the present disclosure are not limited thereto. For example, the first optical layer 117a can be configured by siloxane in which micro metal particles, such as titanium dioxide (TiO2) particles, are dispersed, but the example embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a can improve extraction efficiency of light emitted from the plurality of micro LEDs (ED).

For example, the first optical layer 117a can be disposed in each of the plurality of pixels PX or disposed in some pixel PX disposed in the same row together, but the example embodiments of the present disclosure are not limited thereto. For example, the first optical layer 117a is disposed in each of the plurality of pixels PX or the plurality of pixels PX can share one first optical layer 117a. As another example, each of the plurality of sub pixels separately includes the first optical layer 117a, but the example embodiments of the present disclosure are not limited thereto.

According to the present disclosure, in the active area AA, a second optical layer 117b can be disposed on the passivation layer 116. For example, the second optical layer 117b can be disposed so as to enclose the first optical layer 117a. For example, the second optical layer 117b can be in contact with a side surface of the first optical layer 117a. For example, the second optical layer 117b can be disposed in an area between the plurality of pixels PX. However, the example embodiments of the present disclosure are not limited thereto. For example, the second optical layer 117b can be a diffusion layer, a diffusion window, or a window diffusion layer, but the example embodiments of the present disclosure are not limited thereto.

The second optical layer 117b can be configured by an organic insulating material, but the example embodiments of the present disclosure are not limited thereto. The second optical layer 117b can be configured by the same material as the first optical layer 117a, but the example embodiments of the present disclosure are not limited thereto. For example, the first optical layer 117a can include micro particles, but the second optical layer 117b does not include micro particles. For example, the second optical layer 117b is configured by siloxane, but the example embodiments of the present disclosure are not limited thereto.

For example, a thickness of the first optical layer 117a can be smaller than a thickness of the second optical layer 117b, but the example embodiments of the present disclosure are not limited thereto. Accordingly, in the plan view, an area in which the first optical layer 117a is disposed can include a concave portion which is inwardly dented from an upper surface of the second optical layer 117b.

According to the present disclosure, the second electrode CE2 can be disposed on the first optical layer 117a and the second optical layer 117b. For example, the second electrode CE2 can be electrically connected to the plurality of contact electrodes CCE through a contact hole of the second optical layer 117b. For example, the second electrode CE2 can be disposed on the plurality of micro LEDs (ED). For example, the second electrode CE2 can include a transparent conductive oxide, such as indium tin oxide (ITO) or indium zinc oxide (IZO), but the example embodiments of the present disclosure are not limited thereto. For example, the second electrode CE2 can be disposed to be in contact with the cathode electrode 135. For example, the second electrode CE2 can overlap the first optical layer 117a. For example, the second electrode can cover a plane at the outside of the first optical layer 117a.

The second electrode CE2 can continuously extend in a first direction of the substrate 110. Accordingly, the second electrode can be commonly connected to the plurality of pixels PX disposed in the first direction of the substrate 110. For example, the second electrode CE2 can be commonly connected to the plurality of pixels PX.

According to the present disclosure, the second electrode CE2 can continuously extend on the first optical layer 117a, the second optical layer 117b, and the micro LED (ED). The area in which the first optical layer 117a is disposed can include a concave portion which is inwardly dented from an upper surface of the second optical layer 117b. Accordingly, the first part of the second electrode CE2 disposed on the first optical layer 117a is disposed along the concave portion so that the first part can be disposed to be lower than the second part of the second electrode CE2 disposed on the second optical layer 117b.

The third optical layer 117c can be disposed on the second electrode CE2. The third optical layer 117c can be disposed so as to overlap the plurality of micro LEDs (ED) and the first optical layer 117a. The third optical layer 117c is disposed above the second electrode CE2 and the plurality of micro LEDs (ED) so that mura which can be generated in a part of the plurality of micro LEDs (ED) can be improved. For example, when the plurality of micro LEDs (ED) is transferred onto the substrate 110 of the display panel 100, an area in which the interval between the plurality of micro LEDs (ED) is not uniform can be caused due to the process deviation. When the interval between the plurality of micro LEDs (ED) is not uniform, an emission area of each of the plurality of micro LEDs (ED) is not uniformly disposed so that the mura can be visible to a user. Accordingly, the third optical layer 117c which is configured to uniformly diffuse light is configured above the plurality of micro LEDs (ED) so that light emitted from some micro LED (ED) which is visible as mura can be reduced. Accordingly, light emitted from the plurality of micro LEDs (ED) is uniformly diffused by the third optical layer 117c to be extracted to the outside of the display device 1000 so that the luminance uniformity of the display device 1000 can be improved.

The third optical layer 117c can be configured by an organic insulating material in which micro particles are dispersed, but the example embodiments of the present disclosure are not limited thereto. For example, the third optical layer 117c can be configured by siloxane in which micro metal particles, such as titanium dioxide (TiO2) particles, are dispersed, but the example embodiments of the present disclosure are not limited thereto. For example, the third optical layer 117c is configured by the same material as the first optical layer 117a, but the example embodiments of the present disclosure are not limited thereto. For example, the third optical layer 117c can be a diffusion layer or a upward diffusion layer, but the example embodiments of the present disclosure are not limited thereto.

According to the present disclosure, light from the plurality of micro LEDs (ED) is scattered by micro particles dispersed in the third optical layer 117c to be emitted to the outside of the display device 1000. The third optical layer 117c uniformly mixes light emitted from the plurality of micro LEDs (ED) to further improve the luminance uniformity of the display device 1000. Further, the light extraction efficiency of the display device 1000 can be improved by light scattered from the plurality of micro particles so that the display device 1000 can be driven at a low power.

In the active area AA, a black matrix BM can be disposed on the second electrode CE2, the first optical layer 117a, the second optical layer 117b, and the third optical layer 117c. For example, the contact hole of the second optical layer 117b can be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels can be suppressed.

For example, the black matrix BM can be configured by an opaque material, but the example embodiments of the present disclosure are not limited thereto. For example, the black matrix BM can be configured by an organic insulating material to which black pigment or black dye are added, but the example embodiments of the present disclosure are not limited thereto.

In the active area AA, a cover layer 118 can be disposed on the black matrix BM. The cover layer 118 can protect configurations below the cover layer 118. For example, the cover layer 118 can be configured by an organic insulating material, but the example embodiments of the present disclosure are not limited thereto. For example, the cover layer 118 can be configured by a photo resist, polyimide (PI), or photo acrylic-based material, but the example embodiments of the present disclosure are not limited thereto. For example, the cover layer 118 can be an over coating layer or an insulating layer, but the example embodiments of the present disclosure are not limited thereto.

A polarization layer 293 can be disposed on the cover layer 118 by means of the first adhesive layer 291. A cover member 200 can be disposed on the polarization layer 293 by means of the second adhesive layer 295. For example, the first adhesive layer 291 and the second adhesive layer 295 can include an optically clear adhesive (OCA), an optically clear resin (OCR), or a pressure sensitive adhesive (PSA), but the example embodiments of the present disclosure are not limited thereto.

According to the present disclosure, a plurality of pad electrodes PE can be disposed on the third insulating layer 115c in the second non-active area NA2. For example, at least a part of the plurality of pad electrodes PE can be exposed from the passivation layer 116. For example, the plurality of pad electrodes PE can be electrically connected to the 2-4-th connection line 122d through a contact hole of the third insulating layer 115c.

The adhesive layer ACF can be disposed on the plurality of pad electrodes PE. The adhesive layer ACF can be an adhesive layer in which conductive balls are dispersed in an insulating material, but the example embodiments of the present disclosure are not limited thereto. When heat or a pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) 400, the flexible circuit board (or flexible film) 400 can be attached or bonded to the plurality of pad electrodes PE. For example, the adhesive layer ACF can be anisotropic conductive film, but the example embodiments of the present disclosure are not limited thereto.

The flexible circuit board (or flexible film) 400 can be disposed on the adhesive layer ACF. The flexible circuit board (or flexible film) 400 can be electrically connected to the plurality of pad electrodes PE through the adhesive layer ACF. Accordingly, a signal output from the flexible circuit board (or flexible film) 400 and the printed circuit board 500 can be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

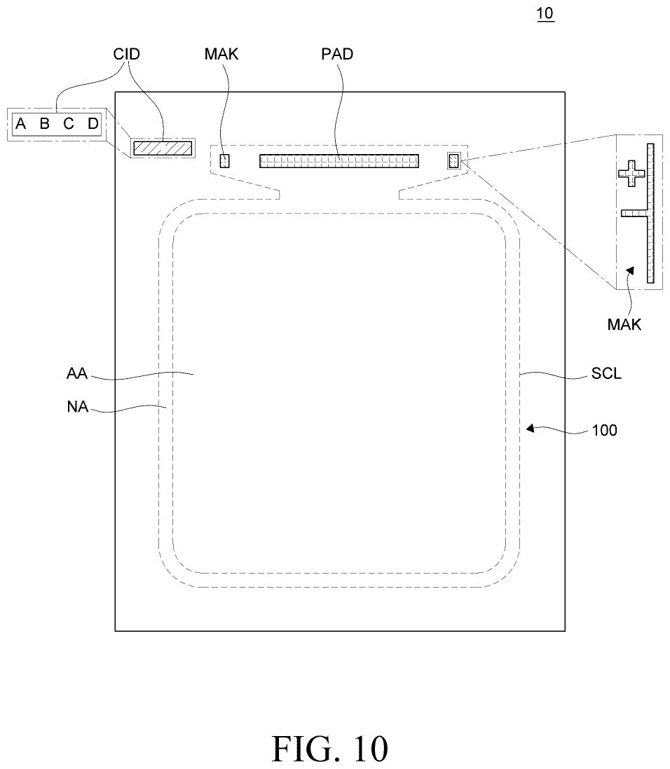

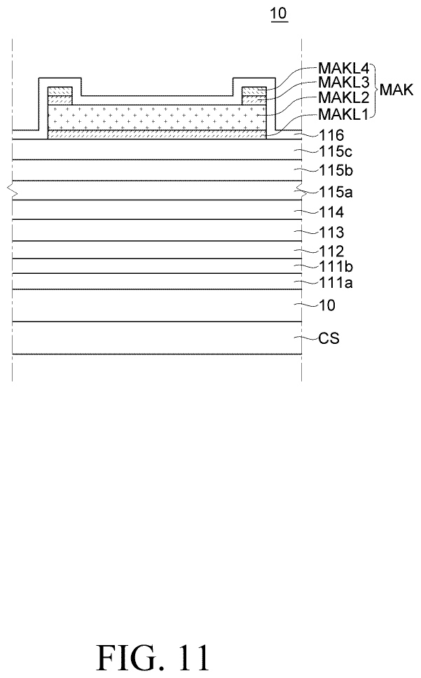

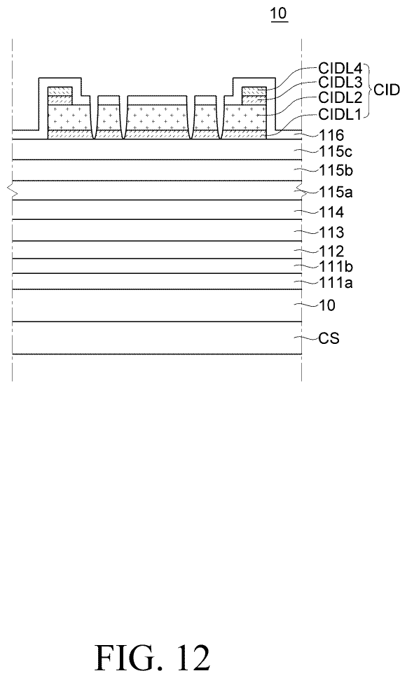

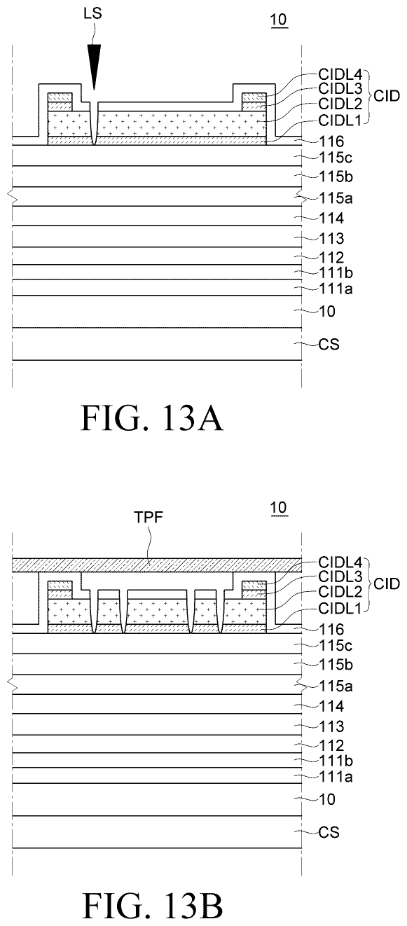

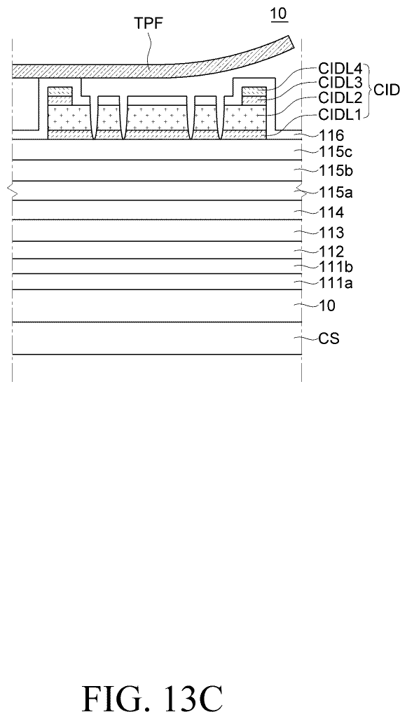

FIG. 10 is a plan view of a mother substrate according to an example embodiment of the present disclosure. FIGS. 11 and 12 are cross-sectional views of a mother substrate according to an example embodiment of the present disclosure. FIGS. 13A to 13C are views for explaining a manufacturing process of a display device according to an example embodiment of the present disclosure. For example, FIG. 10 is a plan view illustrating one cell of a plurality of cells of a mother substrate. For example, FIG. 11 is a cross-sectional view of a module alignment key and FIG. 12 is a cross-sectional view of a cell ID. For example, FIG. 13A is a cross-sectional view for explaining a process of forming a cell ID and FIGS. 13B and 13C are cross-sectional views for explaining a process of transferring a display panel for a module process.

Referring to FIGS. 10 to 13C, the mother substrate 10 is a large size substrate for manufacturing a plurality of display panels 100 and is configured by one or more cells. One cell is an area corresponding to one display panel and a plurality of cells is defined in the mother substrate 10. After forming the display panel 100 in each of the plurality of cells of the mother substrate 10, the mother substrate 10 is cut in the unit of cells to simultaneously form a plurality of display panels 100.

A scribing line SCL is defined on the mother substrate 10. The scribing line SCL is a cut line which defines the display panel 100 and the mother substrate 10 is cut along the scribing line SCL to form the display panel 100. The scribing line SCL has a shape corresponding to a shape of the substrate 110 of the display panel 100. A part of the mother substrate 10 cut along the scribing line SCL can become a substrate 110 of the display panel 100.

A carrier substrate CS which supports the mother substrate 10 is disposed below the mother substrate 10. The mother substrate 10 has a flexible property so that a configuration which supports the mother substrate 10 so as not to be deformed during the manufacturing process of the display panel 100 can be necessary. For example, the carrier substrate CS having a rigidity, such as a glass, is disposed below the mother substrate 10 to support the mother substrate 10 to be flat. Thereafter, when the manufacturing process of the display panel 100 is completed, the carrier substrate CS can be removed.

The cell ID CID is formed on the mother substrate 10. The cell ID CID is provided to represent history information of the display panel 100. For example, the cell ID CID includes history information, such as a manufacturing date and a model name of the display panel 100 and the cell ID CID is identified to confirm the information of the display panel 100. For example, when a plurality of cells and the plurality of display panels 100 are formed on the mother substrate 10, a cell ID CID including information of the display panel 100 can be formed in each of the plurality of cells.

The cell ID CID is disposed to be adjacent to the display panel 100. For example, the cell ID CID is formed in an outside of the display panel 100, for example, an outside area of the scribing line SCL. In this case, during the process of cutting the mother substrate 10 along the scribing line SCL, the cell ID CID is separated and removed from the display panel 100. However, the cell ID CID can also be formed in the display panel 100, but is not limited thereto.

A plurality of module alignment keys MAK is disposed in the display panel 100. The plurality of module alignment keys MAK is configured to identify a position during a manufacturing process of bonding the flexible circuit board (or flexible film) 400 and the printed circuit board 500 to the pad unit PAD of the display panel 100. The plurality of module alignment keys MAK is configured to align a position of the flexible circuit board (or flexible film) 400 which is bonded onto the pad unit PAD.

The plurality of module alignment keys MAK is disposed to be adjacent to the pad unit PAD in the display panel 100. For example, the plurality of module alignment keys MAK is disposed in the second non-active area NA2 in which the pad unit PAD is formed. The position of the pad unit PAD is identified using the plurality of module alignment keys MAK.

The plurality of module alignment keys MAK is formed with various shapes. For example, a planar shape of the plurality of module alignment keys MAK is formed of a combination of various shapes, such as a circular shape, a polygonal shape, or a cross-shape.

Referring to FIGS. 11 and 12, the module alignment keys MAK and the cell ID CID can be configured by a plurality of conductive layers. For example, the module alignment key MAK includes a first alignment conductive layer MAKL1, a second alignment conductive layer MAKL2, a third alignment conductive layer MAKL3, and a fourth alignment conductive layer MAKL4. For example, the cell ID CID includes a first ID conductive layer CIDL1, a second ID conductive layer CIDL2, a third ID conductive layer CIDL3, and a fourth ID conductive layer CIDL4.

For example, the module alignment key MAK and the cell ID CID are formed by the same mask process as the first electrode CE1 and the plurality of conductive layers of each of the module alignment key MAK, the cell ID CID, and the first electrode CE1 is formed of the same material. For example, the plurality of conductive layers of the first electrode CE1, the plurality of alignment conductive layers of the module alignment key MAK, and the plurality of ID conductive layers of the cell ID CID can be formed by layers of the same material. For example, the plurality of conductive layers of the first electrode CE1, the plurality of alignment conductive layers of the module alignment key MAK, and the plurality of ID conductive layers of the cell ID CID can be formed by the same process to be located on the same layer with the same material.

Referring to FIG. 11, the first alignment conductive layer MAKL1 of the module alignment key MAK is disposed on the third insulating layer 115c. The second alignment conductive layer MAKL2 is disposed on the first alignment conductive layer MAKL1. The third alignment conductive layer MAKL3 is disposed on the second alignment conductive layer MAKL2 and the fourth alignment conductive layer MAKL4 is disposed on the third alignment conductive layer MAKL3.

Each of the first alignment conductive layer MAKL1, the second alignment conductive layer MAKL2, the third alignment conductive layer MAKL3, and the fourth alignment conductive layer MAKL4 are configured by titanium (Ti), molybdenum (Mo), aluminum (Al), or titanium (Ti) and indium tin oxide (ITO), but the example embodiments of the present disclosure are not limited thereto. For example, the first alignment conductive layer MAKL1 and the third alignment conductive layer MAKL3 include titanium (Ti) or molybdenum (Mo). The second alignment conductive layer MAKL2 includes aluminum (Al). The fourth alignment conductive layer MAKL4 includes a transparent conductive oxide layer, such as indium tin oxide (ITO) or indium zinc oxide (IZO), which has corrosion resistance and acid resistance. However, the example embodiments of the present disclosure are not limited thereto.

According to the present disclosure, some alignment conductive layer having a good reflection efficiency, among the plurality of alignment conductive layers which configure the module alignment key MAK, is exposed to easily identify the module alignment key MAK. For example, the second alignment conductive layer MAKL2, among the plurality of alignment conductive layers of the module alignment keys MAK, includes a reflective material, such as aluminum (Al). The second alignment conductive layer MAKL2 is formed of a material having a reflection efficiency higher than the first alignment conductive layer MAKL1 and the third alignment conductive layer MAKL3 which are formed of titanium (Ti) and molybdenum (Mo). Therefore, the second alignment conductive layer MAKL2 has a high reflection efficiency so that it is easily identified during the manufacturing process. Further, positions of the pad unit PAD and the flexible circuit board (or flexible film) 400 and the printed circuit board 500 are aligned based on the second alignment conductive layer MAKL2.

For example, in order to expose the second alignment conductive layer MAKL2, the third alignment conductive layer MAKL3 and the fourth alignment conductive layer MAKL4 which cover the second alignment conductive layer MAKL2 can be partially removed or etched. For example, after sequentially depositing the first alignment conductive layer MAKL1, the second alignment conductive layer MAKL2, the third alignment conductive layer MAKL3, and the fourth alignment conductive layer MAKL4, the photolithographic process and the etching process are performed to form the module alignment key MAK. At this time, parts of the third alignment conductive layer MAKL3 and the fourth alignment conductive layer MAKL4 are removed or etched together to expose a top surface of the second alignment conductive layer MAKL2.

For example, a part corresponding to an edge portion (or a boundary portion) of the module alignment key MAK, among the third alignment conductive layer MAKL3 and the fourth alignment conductive layer MAKL4 of the module alignment key MAK, remains and a remaining part excluding the part is removed. For example, an edge portion (or a boundary portion) of each of the third alignment conductive layer MAKL3 formed of titanium (Ti) and the fourth alignment conductive layer MAKL4 formed of indium tin oxide (ITO) may not be etched. Therefore, corrosion of the alignment conductive layer of the module alignment key MAK due to a tetraMethylAmmoniumHydroxide (TMAH) solution used for the mask process of the first electrode CE1, the module alignment key MAK, and the cell ID CID is suppressed.

A passivation layer 116 can cover the module alignment key MAK. The passivation layer 116 is formed on the front surface of the mother substrate 10 on which the module alignment key MAK and the first electrode CE1 are formed to protect the module alignment key MAK.

Referring to FIG. 12, the first ID conductive layer CIDL1 of the cell ID CID is disposed on the third insulating layer 115c. The second ID conductive layer CIDL2 is disposed on the first ID conductive layer CIDL1, the third ID conductive layer CIDL3 is disposed on the second ID conductive layer CIDL2, and the fourth ID conductive layer CIDL4 is disposed on the third ID conductive layer CIDL3.

Each of the first ID conductive layer CIDL1, the second ID conductive layer CIDL2, the third ID conductive layer CIDL3, and the fourth ID conductive layer CIDL4 is configured by titanium (Ti), molybdenum (Mo), aluminum (Al), or titanium (Ti) and indium tin oxide (ITO), but the example embodiments of the present disclosure are not limited thereto. For example, the first ID conductive layer CIDL1 and the third ID conductive layer CIDL3 include titanium (Ti) or molybdenum (Mo). The second ID conductive layer CIDL2 includes aluminum (Al). The fourth ID conductive layer CIDL4 includes a transparent conductive oxide layer, such as indium tin oxide (ITO) or indium zinc oxide (IZO), which has corrosion resistance and acid resistance. However, the example embodiments of the present disclosure are not limited thereto.

According to the present disclosure, like the module alignment key MAK and the first electrode CE1, some ID conductive layer having a good reflection efficiency, among the plurality of ID conductive layers which configure the cell ID CID, is exposed to easily identify the cell ID CID. For example, the second ID conductive layer CIDL2, among the plurality of ID conductive layers of the cell ID CID, includes a reflective material, such as aluminum (Al). The second ID conductive layer CIDL2 is formed of a material having a reflection efficiency higher than the first ID conductive layer CIDL1 and the third ID conductive layer CIDL3 which are formed of titanium (Ti) or molybdenum (Mo). Therefore, the second ID conductive layer CIDL2 has a high reflection efficiency so that it can be easily identified during the manufacturing process.

For example, in order to expose the second ID conductive layer CIDL2, the third ID conductive layer CIDL3 and the fourth ID conductive layer CIDL4 which cover the second ID conductive layer CIDL2 can be partially removed or etched. For example, after sequentially depositing the first ID conductive layer CIDL1, the second ID conductive layer CIDL2, the third ID conductive layer CIDL3, and the fourth ID conductive layer CIDL4 on the third insulating layer, the photolithographic process and the etching process are performed to form a cell ID CID. At this time, parts of the third ID conductive layer CIDL3 and the fourth ID conductive layer CIDL4 are removed or etched together to expose a top surface of the second ID conductive layer CIDL2.

For example, a part corresponding to an edge portion (or a boundary portion) of the cell ID CID, among the third ID conductive layer CIDL3 and the fourth ID conductive layer CIDL4 of the cell ID CID, remains and a remaining part excluding the part is removed. For example, an edge portion (or a boundary portion) of each of the third ID conductive layer CIDL3 formed of titanium (Ti) and the fourth ID conductive layer CIDL4 formed of indium tin oxide (ITO) may not be etched. Therefore, corrosion of the ID conductive layer of the cell ID CID due to a tetraMethylAmmoniumHydroxide (TMAH) solution used for the mask process of the first electrode CE1, the module alignment key MAK, and the cell ID CID is suppressed. Accordingly, the third ID conductive layer CIDL3 and the fourth ID conductive layer CIDL4 are disposed only in the edge portion of the cell ID CID.

In a state in which layers up to the passivation layer 116 are formed on the plurality of ID conductive layers, laser is irradiated onto the plurality of ID conductive layers to mark the cell ID CID. For example, the laser is irradiated to pattern the plurality of ID conductive layers which form the cell ID to represent characters or numbers. Therefore, when the cell ID CID is seen on the plane, it is confirmed that the cell ID CID is marked on the second ID conductive layer CIDL2. In this case, the cell ID CID can be easily recognized based on a shade difference between a part in which the second ID conductive layer CIDL2 having a high reflectance is patterned and a part in which the second ID conductive layer is not patterned.

In the meantime, in the display device according to the example embodiment of the present disclosure, the second ID conductive layer CIDL2 and the second alignment conductive layer MAKL2 having a high reflectance, among the plurality of conductive layers of the cell ID and the module alignment key MAK, are exposed. Therefore, the torn-off of the passivation layer 116 during a subsequent process can be suppressed while improving a recognition rate of the cell ID CID and the module alignment key MAK.

Referring to FIGS. 13A to 13C, layers up to the module alignment key MAK, the cell ID, and the passivation layer 116 are formed during the manufacturing process of the display panel 100. Thereafter, the display panel 100 can be transferred to perform a module process for attaching the flexible circuit board (or flexible film) 400 and the printed circuit board 500 to the pad unit PAD.

For example, referring to FIG. 13A, the plurality of ID conductive layers which form the cell ID CID is formed on the third insulating layer 115c, and the third ID conductive layer CIDL3 and the fourth ID conductive layer CIDL4, among the plurality of ID conductive layers, are partially etched to expose the second ID conductive layer CIDL2. A remaining part of the third ID conductive layer CIDL3 and the fourth ID conductive layer CIDL4 excluding the edge portion is removed to expose the second ID conductive layer CIDL2 in the most area of the cell ID CID.

Next, the passivation layer 116 is formed on the plurality of ID conductive layers. The passivation layer 116 is in contact with the second ID conductive layer CIDL2 in the most area of the cell ID CID. Finally, a process of marking an ID on the plurality of ID conductive layers which are covered by the passivation layer 116 is performed to form the cell ID CID.

Referring to FIG. 13B, after forming the cell ID CID and the module alignment key MAK on the mother substrate 10, a protection film TPF is attached onto the mother substrate 10. The protection film TPF is a film having an adhesion and protects configurations formed on the mother substrate 10 while transferring the mother substrate 10. The protection film TPF can be disposed so as to cover the front surface of the mother substrate 10. For example, the protection film TPF which is disposed to cover the entire surface of the mother substrate 10 is in contact with the passivation layer 116 which covers the cell ID CID. For example, the protection film TPF is in contact with at least a part of the passivation layer 116 which covers the fourth ID conductive layer CIDL4 and the second ID conductive layer CIDL2 of the cell ID CID.

Next, referring to FIG. 13C, in a state in which the protection film TPF is attached onto the mother substrate 10, after transferring the mother substrate 10 to a position where the module process is performed, the protection film TPF is removed to perform the module process.

At this time, the passivation layer 116 which is formed of an inorganic material, such as silicon nitride (SiNx) has poor adhesion with the transparent conductive oxide, such as indium tin oxide (ITO) so that it is easily separated. For example, in a state in which the passivation layer 116 is attached onto a configuration formed of a transparent conductive oxide, if the protection film TPF is released, the passivation layer 116 is easily lifted from the configuration formed of the transparent conductive oxide to cause a damage on the passivation layer 116.

Specifically, the fourth ID conductive layer CIDL4 formed of indium tin oxide (ITO) is disposed on the uppermost end of the plurality of ID conductive layers which form the cell ID CID. Therefore, the larger the contact area between the passivation layer 116 which covers the cell ID and the fourth ID conductive layer CIDL4, the higher the probability of generating an area where the fourth ID conductive layer CIDL4 and the passivation layer 116 are separated. Therefore, in the display device 1000 according to the example embodiment of the present disclosure, the fourth ID conductive layer CIDL4 is removed from the most area excluding the edge portion of the cell ID CID to minimize the contact area of the passivation layer 116 and the fourth ID conductive layer CIDL4. Further, the torn-off of the passivation layer 116 during the process of removing the protection film TPF is minimized.

Further, the passivation layer 116 has an adhesive characteristic with the second ID conductive layer CIDL2 which is formed of aluminum (Al) superior to the fourth ID conductive layer CIDL4 formed of transparent conductive oxide. For example, an interfacial characteristic between the passivation layer 116 and the second ID conductive layer CIDL2 is superior to an interfacial characteristic between the passivation layer 116 and the fourth ID conductive layer CIDL4. Therefore, the adhesive characteristic between the passivation layer 116 and the second ID conductive layer CIDL2 is excellent so that the lifting or separating of the passivation layer 116 from the second ID conductive layer CIDL2 during the process of removing the protection film TPF is minimized.

Likewise, as described with reference to FIG. 11, the second alignment conductive layer MAKL2 is exposed in the remaining part of the plurality of module alignment keys MAK excluding the edge portion. Therefore, the contact area between the fourth alignment conductive layer MAKL4 and the passivation layer 116 having a poor interfacial characteristic can be minimized. Accordingly, when the protection film TPF on the plurality of module alignment keys MAK is removed, the lifting or torn-off of the passivation layer 116 can be minimized. Further, in the display device 1000 according to the example embodiment of the present disclosure, among the plurality of ID conductive layers of the cell ID CID, the second ID conductive layer CIDL2 has a reflective characteristic better than the third ID conductive layer CIDL3. Therefore, when the fourth ID conductive layer CIDL4 is patterned, the third ID conductive layer CIDL3 is patterned together to expose the second ID conductive layer CIDL2. For example, the second ID conductive layer CIDL2 formed of aluminum (Al) has a reflective characteristic superior to the third ID conductive layer CIDL3 formed of titanium (Ti). Therefore, when the fourth ID conductive layer CIDL4 is etched, the third ID conductive layer CIDL3 is also etched to expose the second ID conductive layer CIDL2, thereby improving the recognition rate of the cell ID CID.

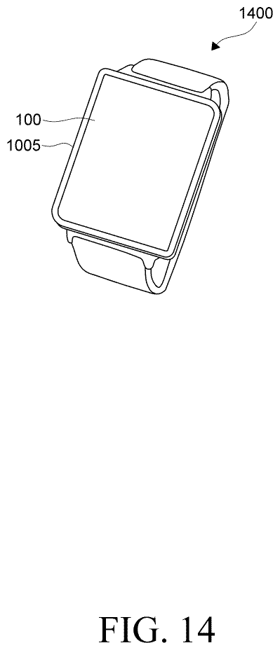

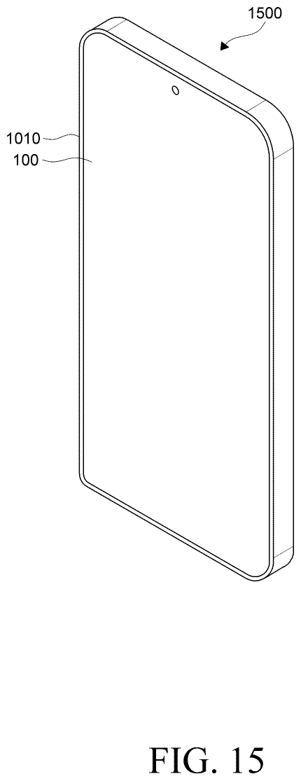

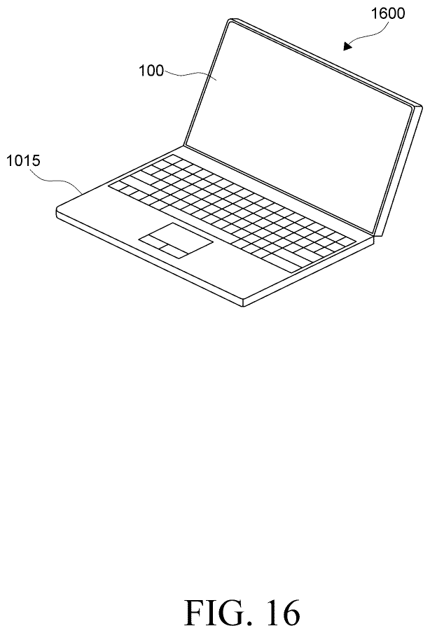

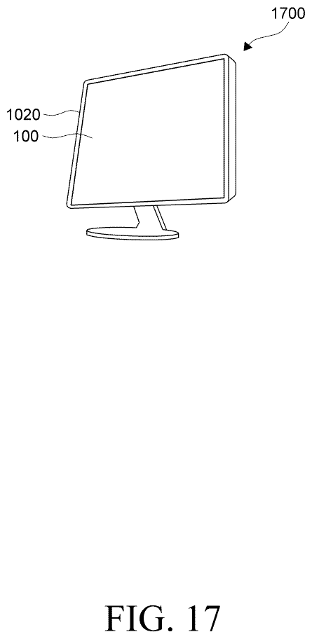

FIGS. 14 to 17 are views illustrating devices to which a display device according to example embodiments of the present disclosure is applied.

Referring to FIGS. 14 to 17, the display devices 1000 according to the example embodiments of the present disclosure can be included in various devices or electronic devices. For example, referring to FIGS. 14 to 17, various electronic device can include a wearable device 1400, a mobile device 1500, a notebook 1600, and a monitor or TV 1700, but the example embodiments of the present disclosure are not limited thereto.

The wearable device 1400, the mobile device 1500, the notebook 1600, and a monitor or TV 1700 can include case units 1005, 1010, 1015, and 1020 and display panel 100 and the display devices 1000 according to the example embodiments of the present disclosure which have been described in FIGS. 1 to 13C, respectively.

For example, the display devices 1000 according to the example embodiment of the present disclosure can be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic note, an electronic book, a portable multimedia player (PMP), a personal digital assistant (PDA), an MP3 player, a mobile medical apparatus, a desktop PC, a laptop PC, a netbook computer, a workstation, a navigation, a display device for a vehicle, a theatrical display device, a television, a wallpaper device, a signage device, a game device, a notebook, a monitor, a camera, a camcorder, and a consumer electronics device.

The example embodiments of the present disclosure can also be described as follows:

According to an aspect of the present disclosure, a display device includes a substrate, one or more pixel driving circuits disposed on the substrate, a plurality of micro LEDs which are disposed on the pixel driving circuits and are electrically connected to the pixel driving circuits, and a plurality of first electrodes which are electrically connected to the plurality of micro LEDs and the pixel driving circuits. Each of the plurality of first electrodes includes a first conductive layer, a second conductive layer disposed on the first conductive layer, a third conductive layer on the second conductive layer, and a fourth conductive layer on the third conductive layer, and at least a part of a top surface of the second conductive layer is exposed from the third conductive layer and the fourth conductive layer.

The display device can further include a plurality of signal lines which electrically connect the plurality of first electrodes and the pixel driving circuits. The plurality of first electrodes and the plurality of signal lines can be configured to transmit an anode voltage output from the pixel driving circuits to the plurality of micro LEDs.

The display device can further include a plurality of contact electrodes which are electrically connected to the pixel driving circuits, and one or more second electrodes which are electrically connected to the plurality of contact electrodes. The second electrodes and the plurality of contact electrodes can be configured to transmit a cathode voltage output from the pixel driving circuits to the plurality of micro LEDs.

The display device can further include an insulating layer which is disposed below the plurality of signal lines, the plurality of first electrodes, the plurality of contact electrodes, and the second electrodes, and a passivation layer which covers the plurality of signal lines, the plurality of first electrodes, and the plurality of contact electrodes. The passivation layer can be in contact with at least a part of the top surface of the second conductive layer of each of the plurality of first electrodes.

The display device can further include a solder pattern which is disposed between each of the plurality of first electrodes and each of the plurality of micro LEDs. In each of the plurality of first electrodes, the third conductive layer and the fourth conductive layer can be disposed so as to correspond to a portion overlapping edge portions of the plurality of first electrodes and the solder pattern.

The second conductive layer can be exposed from the third conductive layer and the fourth conductive layer in the remaining portion excluding the portion overlapping the edge portions of the plurality of first electrodes and the solder pattern.

The display device can further include a plurality of module alignment keys disposed between the insulating layer and the passivation layer. Each of the plurality of module alignment keys can include a first alignment conductive layer which is disposed on the insulating layer and is formed of the same material as the first conductive layer, a second alignment conductive layer which is disposed on the first alignment conductive layer and is formed of the same material as the second conductive layer, a third alignment conductive layer which is disposed on the second alignment conductive layer and is formed of the same material as the third conductive layer, and a fourth alignment conductive layer which is disposed on the third alignment conductive layer and is formed of the same material as the fourth conductive layer.

In each of the plurality of module alignment keys, the third alignment conductive layer and the fourth alignment conductive layer can be disposed so as to correspond to edge portions of the plurality of module alignment keys, and in a remaining portion excluding the edge portions of the plurality of module alignment keys, a top surface of the second alignment conductive layer can be exposed from the third alignment conductive layer and the fourth alignment conductive layer.

The first conductive layer and the first alignment conductive layer and the third conductive layer and the third alignment conductive layer can be formed of the same opaque conductive material, the fourth conductive layer and the fourth alignment conductive layer can be formed of a transparent conductive material, and the second conductive layer and the second alignment conductive layer can be formed of an opaque conductive material which has a reflection efficiency higher than that of the third conductive layer and the third alignment conductive layer.

The first conductive layer, the first alignment conductive layer, the third conductive layer, and the third alignment conductive layer can be formed of titanium (Ti) and the second conductive layer and the second alignment conductive layer can be formed of aluminum (Al).

Each of the plurality of micro LEDs can include an anode electrode, a first semiconductor layer disposed on the anode electrode, an active layer on the first semiconductor layer, a second semiconductor layer on the active layer, and a cathode electrode on the second semiconductor layer.

The display device can further include a solder pattern which is disposed between the plurality of first electrodes and the anode electrodes of the plurality of micro LEDs. The plurality of first electrodes and the anode electrodes can be electrically connected by eutectic bonding using the solder pattern.

According to an aspect of the present disclosure, a mother substrate for a display device including one or more scribing lines which define a display panel includes a plurality of micro LEDs disposed in an inside area of the scribing lines, one or more pixel driving circuits disposed in the inside area of the scribing lines, a plurality of first electrodes which are disposed in the inside area of the scribing lines, and electrically connect the plurality of micro LEDs and the pixel driving circuits, and each of which includes a plurality of conductive layers, a plurality of module alignment keys which are disposed in the inside area of the scribing lines and each of which includes a plurality of alignment conductive layers, and a plurality of cell IDs which are disposed in an outside area of the scribing lines, and each of which includes a plurality of ID conductive layers. The plurality of conductive layers, the plurality of alignment conductive layers, and the plurality of ID conductive layers are formed with a multi-layered structure with the same material.

The plurality of conductive layers can include a first conductive layer, a second conductive layer disposed on the first conductive layer, a third conductive layer on the second conductive layer, and a fourth conductive layer on the third conductive layer, the plurality of alignment conductive layers can include a first alignment conductive layer, a second alignment conductive layer disposed on the first alignment conductive layer, a third alignment conductive layer on the second alignment conductive layer, and a fourth alignment conductive layer on the third alignment conductive layer, the plurality of ID conductive layers can include a first ID conductive layer, a second ID conductive layer disposed on the first ID conductive layer, a third ID conductive layer on the second ID conductive layer, and a fourth ID conductive layer on the third ID conductive layer.

The first conductive layer, the first alignment conductive layer, and the first ID conductive layer can be formed of the same material, the second conductive layer, the second alignment conductive layer, and the second ID conductive layer can be formed of the same material, the third conductive layer, the third alignment conductive layer, and the third ID conductive layer can be formed of the same material, and the fourth conductive layer, the fourth alignment conductive layer, and the fourth ID conductive layer can be formed of the same material.

The fourth conductive layer, the fourth alignment conductive layer, and the fourth ID conductive layer can be formed of a transparent conductive material, the first conductive layer, the first alignment conductive layer, and the first ID conductive layer and the third conductive layer, the third alignment conductive layer, and the third ID conductive layer can be formed of an opaque conductive material, and the second conductive layer, the second alignment conductive layer, and the second ID conductive layer can be formed of an opaque conductive material which has a reflection efficiency higher than that of the first conductive layer and the third conductive layer.

At least a part of a top surface of the second conductive layer can be exposed from the third conductive layer and the fourth conductive layer, in each of the plurality of first electrodes, at least a part of a top surface of the second alignment conductive layer can be exposed from the third alignment conductive layer and the fourth alignment conductive layer, in each of the plurality of module alignment keys, and at least a part of a top surface of the second ID conductive layer can be exposed from the third ID conductive layer and the fourth ID conductive layer, in each of the plurality of cell IDs.

The third conductive layer and the fourth conductive layer can be partially disposed so as to correspond to each of edge portions and center portions of each of the plurality of first electrodes, the third alignment conductive layer and the fourth alignment conductive layer can be partially disposed so as to correspond to edge portions of each of the plurality of module alignment keys, and the third ID conductive layer and the fourth ID conductive layer can be partially disposed so as to correspond to edge portions of each of the plurality of cell IDs.

Each of the plurality of micro LEDs can include an anode electrode, a first semiconductor layer disposed on the anode electrode, an active layer on the first semiconductor layer, a second semiconductor layer on the active layer, and a cathode electrode on the second semiconductor layer.

The mother substrate can further comprise a solder pattern which is disposed between the plurality of first electrodes and the anode electrodes of the plurality of micro LEDs. The plurality of first electrodes and the anode electrodes can be electrically connected by eutectic bonding using the solder pattern.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate;
one or more pixel driving circuits disposed on the substrate;
a plurality of micro light emitting diodes (LEDs) which are disposed on the one or more pixel driving circuits and are electrically connected to the one or more pixel driving circuits; and
a plurality of first electrodes which are electrically connected to the plurality of micro LEDs and the one or more pixel driving circuits,
wherein each of the plurality of first electrodes includes:
a first conductive layer;
a second conductive layer disposed on the first conductive layer;
a third conductive layer on the second conductive layer; and
a fourth conductive layer on the third conductive layer, and
wherein at least a part of a top surface of the second conductive layer is exposed from the third conductive layer and the fourth conductive layer.

2. The display device according to claim 1, further comprising:
a plurality of signal lines which electrically connect the plurality of first electrodes and the one or more pixel driving circuits,
wherein the plurality of first electrodes and the plurality of signal lines are configured to transmit an anode voltage output from the one or more pixel driving circuits to the plurality of micro LEDs.

3. The display device according to claim 2, further comprising:
a plurality of contact electrodes which are electrically connected to the one or more pixel driving circuits; and
one or more second electrodes which are electrically connected to the plurality of contact electrodes,
wherein the one or more second electrodes and the plurality of contact electrodes are configured to transmit a cathode voltage output from the one or more pixel driving circuits to the plurality of micro LEDs.

4. The display device according to claim 3, further comprising:
an insulating layer which is disposed below the plurality of signal lines, the plurality of first electrodes, the plurality of contact electrodes, and the one or more second electrodes; and
a passivation layer which covers the plurality of signal lines, the plurality of first electrodes, and the plurality of contact electrodes,
wherein the passivation layer is in contact with at least a part of the top surface of the second conductive layer of each of the plurality of first electrodes.

5. The display device according to claim 4, further comprising:
a solder pattern which is disposed between each of the plurality of first electrodes and one of the plurality of micro LEDs,
wherein in each of the plurality of first electrodes, the third conductive layer and the fourth conductive layer are disposed so as to correspond to a portion overlapping edge portions of the plurality of first electrodes and the solder pattern.

6. The display device according to claim 5, wherein the second conductive layer is exposed from the third conductive layer and the fourth conductive layer in a remaining portion excluding the portion overlapping the edge portions of the plurality of first electrodes and the solder pattern.

7. The display device according to claim 4, further comprising:
a plurality of module alignment keys disposed between the insulating layer and the passivation layer,
wherein each of the plurality of module alignment keys includes:
a first alignment conductive layer which is disposed on the insulating layer and includes a same material as the first conductive layer;
a second alignment conductive layer which is disposed on the first alignment conductive layer and includes a same material as the second conductive layer;
a third alignment conductive layer which is disposed on the second alignment conductive layer and includes a same material as the third conductive layer; and
a fourth alignment conductive layer which is disposed on the third alignment conductive layer and includes a same material as the fourth conductive layer.

8. The display device according to claim 7, wherein in each of the plurality of module alignment keys, the third alignment conductive layer and the fourth alignment conductive layer are disposed so as to correspond to edge portions of the plurality of module alignment keys, and
in a remaining portion excluding the edge portions of the plurality of module alignment keys, a top surface of the second alignment conductive layer is exposed from the third alignment conductive layer and the fourth alignment conductive layer.

9. The display device according to claim 7, wherein the first conductive layer, the first alignment conductive layer, the third conductive layer and the third alignment conductive layer include a same opaque conductive material,
the fourth conductive layer and the fourth alignment conductive layer include a transparent conductive material, and
the second conductive layer and the second alignment conductive layer include an opaque conductive material which has a reflection efficiency higher than that of the third conductive layer and the third alignment conductive layer.

10. The display device according to claim 9, wherein the first conductive layer, the first alignment conductive layer, the third conductive layer, and the third alignment conductive layer include titanium Ti, and
the second conductive layer and the second alignment conductive layer include aluminum Al.

11. The display device according to claim 1, wherein each of the plurality of micro LEDs includes:
an anode electrode;
a first semiconductor layer disposed on the anode electrode;
an active layer on the first semiconductor layer;
a second semiconductor layer on the active layer; and
a cathode electrode on the second semiconductor layer.

12. The display device according to claim 11, further comprising:
a solder pattern which is disposed between the plurality of first electrodes and the anode electrodes of the plurality of micro LEDs,
wherein the plurality of first electrodes and the anode electrodes are electrically connected by eutectic bonding using the solder pattern.

13. A mother substrate having one or more scribing lines for defining at least one display panel, the mother substrate comprising:
a plurality of micro light emitting diodes (LEDs) disposed in an inside area of the one or more scribing lines;
one or more pixel driving circuits disposed in the inside area of the one or more scribing lines;
a plurality of first electrodes which are disposed in the inside area of the one or more scribing lines, and electrically connect the plurality of micro LEDs and the one or more pixel driving circuits, each of the plurality of first electrodes including a plurality of conductive layers;
a plurality of module alignment keys which are disposed in the inside area of the one or more scribing lines, each of the plurality of module alignment keys including a plurality of alignment conductive layers; and
a plurality of cell identifications (IDs) which are disposed in an outside area of the one or more scribing lines, each of the plurality of cell IDs including a plurality of ID conductive layers,
wherein the plurality of conductive layers, the plurality of alignment conductive layers, and the plurality of ID conductive layers have a multi-layered structure and include a same material.

14. The mother substrate according to claim 13,
wherein the plurality of conductive layers include:
a first conductive layer;
a second conductive layer disposed on the first conductive layer;
a third conductive layer on the second conductive layer; and
a fourth conductive layer on the third conductive layer,
wherein the plurality of alignment conductive layers include:
a first alignment conductive layer;
a second alignment conductive layer disposed on the first alignment conductive layer;
a third alignment conductive layer on the second alignment conductive layer; and
a fourth alignment conductive layer on the third alignment conductive layer, and
wherein the plurality of ID conductive layers include:
a first ID conductive layer;
a second ID conductive layer disposed on the first ID conductive layer;
a third ID conductive layer on the second ID conductive layer; and
a fourth ID conductive layer on the third ID conductive layer.

15. The mother substrate according to claim 14, wherein the first conductive layer, the first alignment conductive layer, and the first ID conductive layer include a same material,
the second conductive layer, the second alignment conductive layer, and the second ID conductive layer include a same material,
the third conductive layer, the third alignment conductive layer, and the third ID conductive layer include a same material, and
the fourth conductive layer, the fourth alignment conductive layer, and the fourth ID conductive layer include a same material.

16. The mother substrate according to claim 15, wherein the fourth conductive layer, the fourth alignment conductive layer, and the fourth ID conductive layer include a transparent conductive material,
the first conductive layer, the first alignment conductive layer, the first ID conductive layer, the third conductive layer, the third alignment conductive layer, and the third ID conductive layer include an opaque conductive material, and
the second conductive layer, the second alignment conductive layer, and the second ID conductive layer include an opaque conductive material which has a reflection efficiency higher than that of the first conductive layer and the third conductive layer.

17. The mother substrate according to claim 16, wherein at least a part of a top surface of the second conductive layer is exposed from the third conductive layer and the fourth conductive layer, in each of the plurality of first electrodes,
at least a part of a top surface of the second alignment conductive layer is exposed from the third alignment conductive layer and the fourth alignment conductive layer, in each of the plurality of module alignment keys, and
at least a part of a top surface of the second ID conductive layer is exposed from the third ID conductive layer and the fourth ID conductive layer, in each of the plurality of cell IDs.

18. The mother substrate according to claim 17, wherein the third conductive layer and the fourth conductive layer are partially disposed so as to correspond to each of edge portions and center portions of each of the plurality of first electrodes,
the third alignment conductive layer and the fourth alignment conductive layer are partially disposed so as to correspond to edge portions of each of the plurality of module alignment keys, and
the third ID conductive layer and the fourth ID conductive layer are partially disposed so as to correspond to edge portions of each of the plurality of cell IDs.

19. The mother substrate according to claim 13, wherein each of the plurality of micro LEDs includes:
an anode electrode;
a first semiconductor layer disposed on the anode electrode;
an active layer on the first semiconductor layer;
a second semiconductor layer on the active layer; and
a cathode electrode on the second semiconductor layer.

20. The mother substrate according to claim 19, further comprising:
a solder pattern which is disposed between the plurality of first electrodes and the anode electrodes of the plurality of micro LEDs,
wherein the plurality of first electrodes and the anode electrodes are electrically connected by eutectic bonding using the solder pattern.
